(19) United States
(12) Patent Application Publication
(10) Pub. No.: US 2024/0405021 A1
(43) Pub. Date: Dec. 5, 2024

(54) TRANSISTOR ISOLATION STRUCTURES AND METHODS OF FORMING THE SAME

(71) Applicant: Taiwan Semiconductor Manufacturing Co., Ltd., Hsinchu (TW)

(72) Inventors: Kuan-Ting Pan, Taipei City (TW); Chia-Hao Chang, Hsinchu (TW); Jia-Chuan You, Dayuan Township (TW); Kuo-Cheng Chiang, Zhubei City (TW); Chih-Hao Wang, Baoshan Township (TW)

(21) Appl. No.: 18/468,409

(22) Filed: Sep. 15, 2023

Related U.S. Application Data
(60) Provisional application No. 63/505,459, filed on Jun. 1, 2023.

(51) Int. Cl. H01L 27/092; H01L 21/8238; H01L 29/06; H01L 29/423; H01L 29/66; H01L 29/775

(52) U.S. Cl. CPC H01L 27/092; H01L 21/823807; H01L 21/823814; H01L 21/823871; H01L 21/823878; H01L 29/0673; H01L 29/42392; H01L 29/66439; H01L 29/66545; H01L 29/775

(57) ABSTRACT

A device includes first nanostructures over a substrate; second nanostructures over the substrate, wherein the first nanostructures are laterally separated from the second nanostructures by an isolation structure between the first nanostructures and the second nanostructures; a first gate structure around each first nanostructure and around each second nanostructure, wherein the first gate structure extends over the isolation structure; third nanostructures over the substrate; and a second gate structure around each third nanostructure, wherein the second gate structure is separated from the first gate structure by a dielectric wall.

### PRIORITY CLAIM AND CROSS-REFERENCE

This application claims the benefit of U.S. Provisional Application No. 63/505,459, filed on Jun. 1, 2023 which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2-16C are views of intermediate stages in the manufacturing of nanostructure-FETs, in accordance with some embodiments.

FIG. 17 illustrates an intermediate stage in the manufacturing of a nanostructure-FET in a three-dimensional view, in accordance with some embodiments.

FIGS. 18A-31B are views of intermediate stages in the manufacturing of nanostructure-FETs, in accordance with some embodiments.

FIGS. 32A and 32B are views of intermediate stages in the manufacturing of nanostructure-FETs, in accordance with some embodiments.

FIG. 33 is a view of an intermediate stage in the manufacturing of nanostructure-FETs, in accordance with some embodiments.

FIGS. 34A-34D are views of intermediate stages in the manufacturing of nanostructure-FETs, in accordance with some embodiments.

FIGS. 35A-35C are magnified views of nanostructure-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, dielectric walls are formed between adjacent groups of vertically-stacked nanostructures. The dielectric walls provide isolation, so the adjacent groups of nanostructures may be formed closer together. Device density may thus be improved. Additionally, gate structures are formed around the nanostructures and along the dielectric walls. The gate structures are x-shaped, thereby allowing reduced end-cap length, which can reduce parasitic capacitances. Further, isolation structures are formed between other groups of vertically-stacked nanostructures. The isolation structures are formed within the gate structures, and can reduce parasitic capacitances between the gate structures and neighboring source/drain regions, thereby improving device performance.

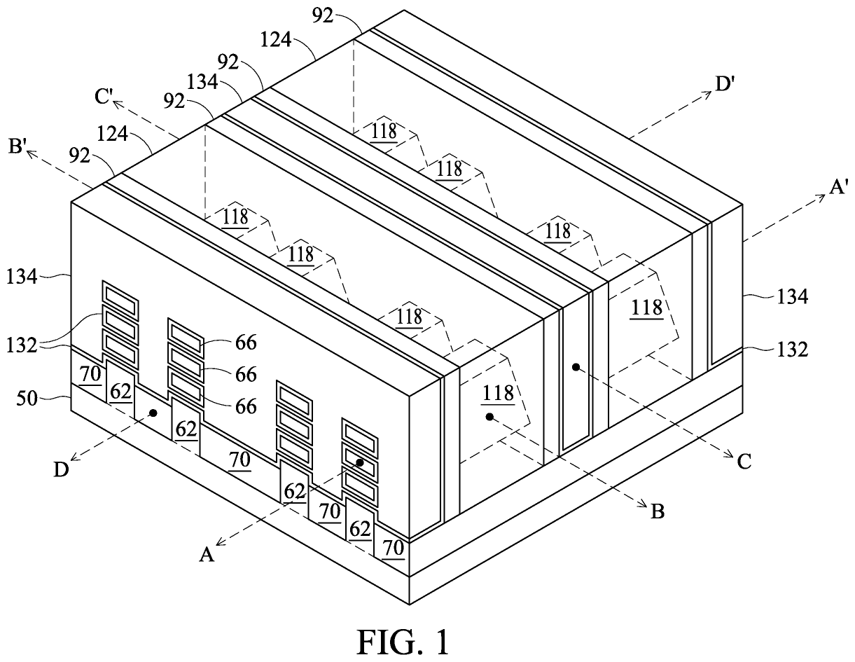

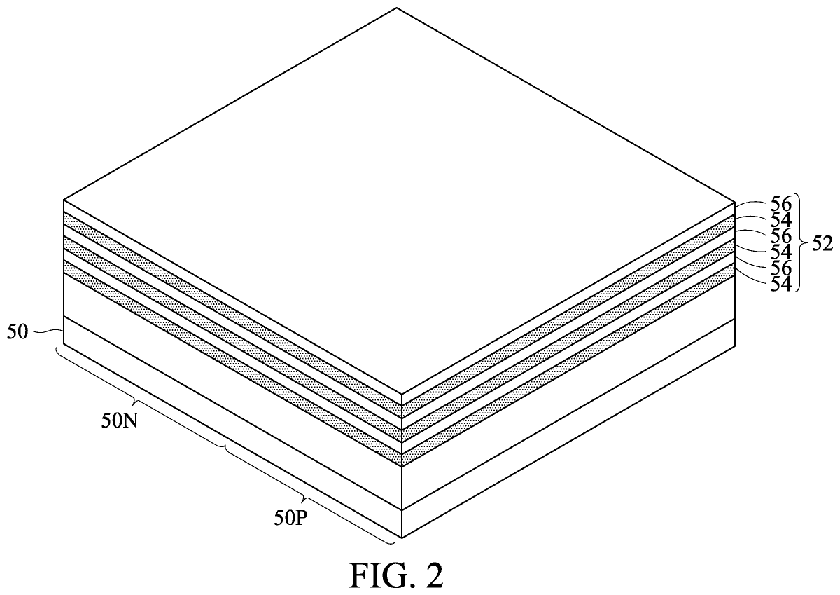

FIG. 1 illustrates an example of nanostructure-FETs (e.g., nanowire FETs, nanosheet FETs, multi bridge channel (MBC) FETs, nanoribbon FETs, gate-all-around (GAA) FETs, or the like), in accordance with some embodiments. FIG. 1 is a three-dimensional view, where some features of the nanostructure-FETs are omitted for illustration clarity.

The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may comprise a single material or a plurality of materials. In this context, the fins 62 refer to the portion extending between the neighboring isolation regions 70.

Gate dielectrics 132 are over top surfaces of the fins 62 and along top surfaces, sidewalls, and bottom surfaces of the nanostructures 66. Gate electrodes 134 are over the gate dielectrics 132. Source/drain regions 118 are disposed on the fins 62 at opposing sides of the gate dielectrics 132 and the gate electrodes 134. Source/drain region(s) 118 may refer to a source or a drain, individually or collectively dependent upon the context. An inter-layer dielectric (ILD) 124 is formed over the source/drain regions 118. Contacts (subsequently described) to the source/drain regions 118 will be formed through the ILD 124. The source/drain regions 118 may be shared between various nanostructures 66. For example, adjacent source/drain regions 118 may be electrically connected, such as through coalescing the source/drain regions 118 by epitaxial growth, or through coupling the source/drain regions 118 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 118 of the nanostructure-FET. Cross-section B-B′ is perpendicular to cross-section A-A′ and extends through source/drain regions 118 of the nanostructure-FETs. Cross-section C-C′ is parallel to cross-section B-B′ and along a longitudinal axis of a gate electrode 134. Subsequent figures refer to these reference cross-sections for clarity. Cross-section D-D′ is parallel to cross-section A-A′ and extends through source/drain regions 118 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

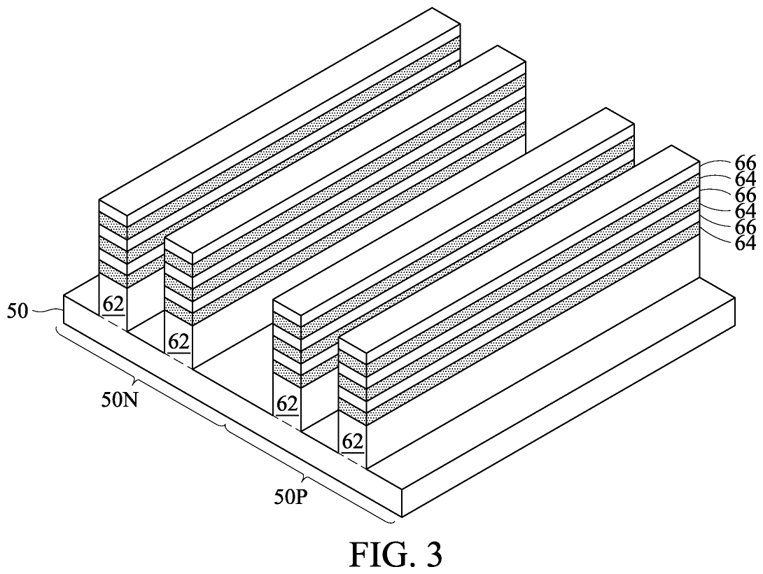

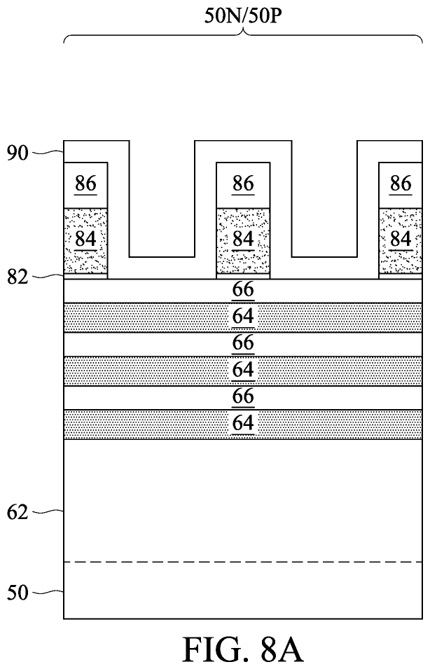

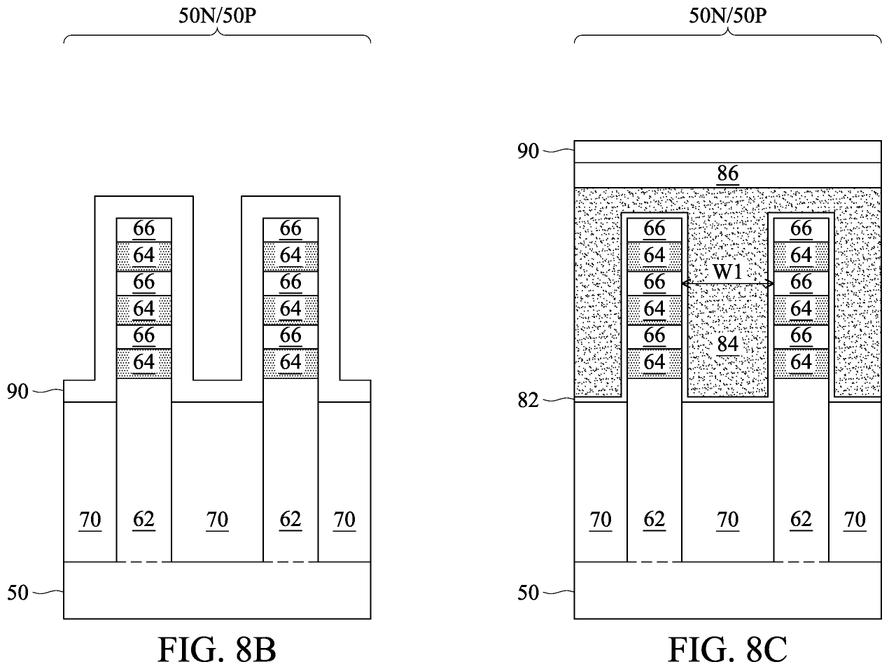

FIGS. 2-16C are views of intermediate stages in the manufacturing of nanostructure-FETs, in accordance with some embodiments. FIGS. 2, 3, 4, 5, 6, and 7 are three-dimensional views showing a similar three-dimensional view as FIG. 1. FIGS. 8A, 9A, 10A, 11A, 12A, 13A, 14A, 14B, 15A, and 16A illustrate cross-sectional views along a similar cross-section as reference cross-section A-A′ in FIG. 1. FIGS. 8B, 9B, 10B, 11B, 12B, 13B, 15B, and 16B illustrate cross-sectional views along a similar cross-section as reference cross-section B-B′ in FIG. 1. FIGS. 8C, 9C, 10C, 11C, 12C, 13C, 15C, and 16C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52.

In FIG. 3, fins 62 are formed in the substrate 50 and nanostructures 64/66 are formed in the multi-layer stack 52. In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56. In some embodiments, groups of nanostructures 64/66 may be formed having a separation width W1 (see FIG. 8C) that is in the range of about 25 nm to about 46 nm, though other widths are possible. In some cases, the embodiments described herein allow for the formation of groups of nanostructures 64/66 having smaller separation widths W1, which can increase device density.

The fins 62 and the nanostructures 64/66 may be patterned by any suitable method. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66.

The fins 62 are illustrated as having substantially equal widths in both the n-type region 50N and the p-type region 50P. In some embodiments, the widths of the fins 62 in the n-type region 50N may be greater or less than the width of the fins 62 in the p-type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and/or be trapezoidal in shape.

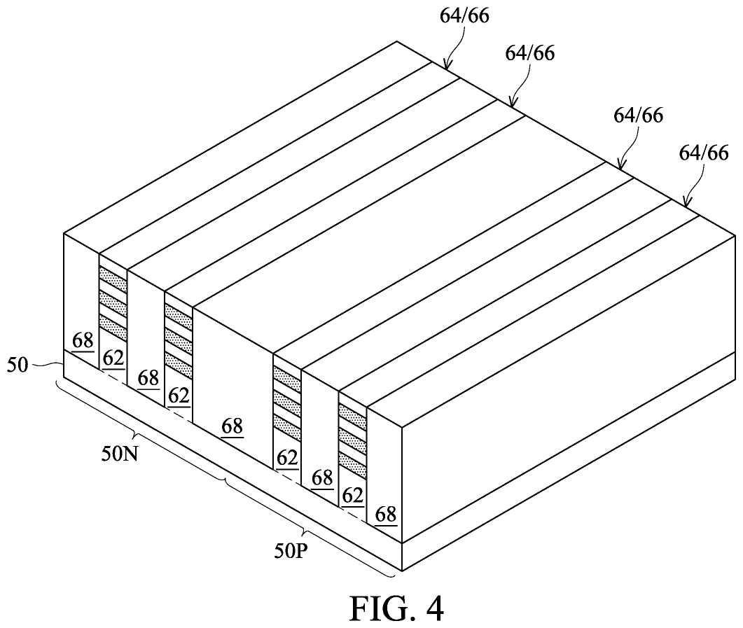

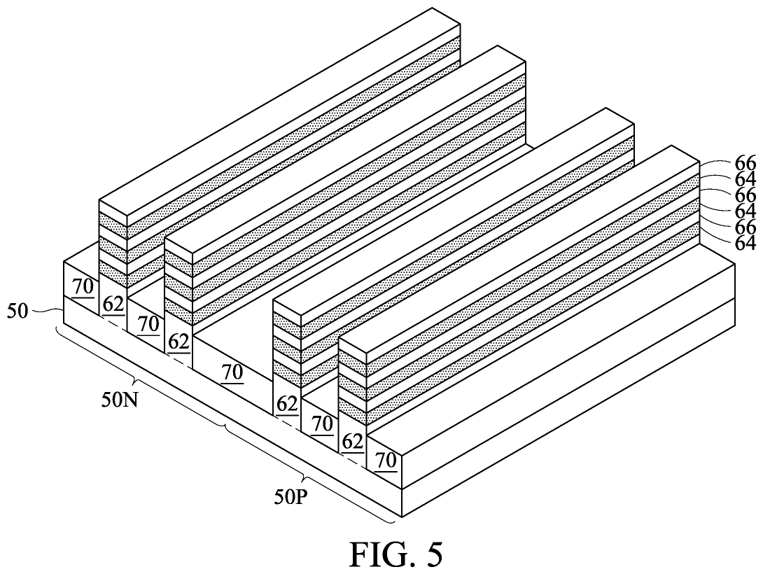

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials may be formed over the liner.

The insulation material 68 may be deposited over the fins 62 and nanostructures 64/66 such that excess insulation material 68 covers the nanostructures 64/66. A removal process may be performed to remove excess insulation material 68 over the nanostructures 64/66. In some embodiments, a planarization process such as a chemical mechanical polish (CMP), an etch-back process, combinations thereof, or the like may be utilized. The planarization process exposes the nanostructures 64/66 such that top surfaces of the nanostructures 64/66 and the insulation material 68 are level after the planarization process is complete.

In FIG. 5, the insulation material 68 is recessed to form STI regions 70. The STI regions 70 are adjacent the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed using an acceptable ashing process or the like.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from 10¹³ atoms/cm³ to 10¹⁴ atoms/cm³. After the implant, the photoresist may be removed using an acceptable ashing process or the like.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

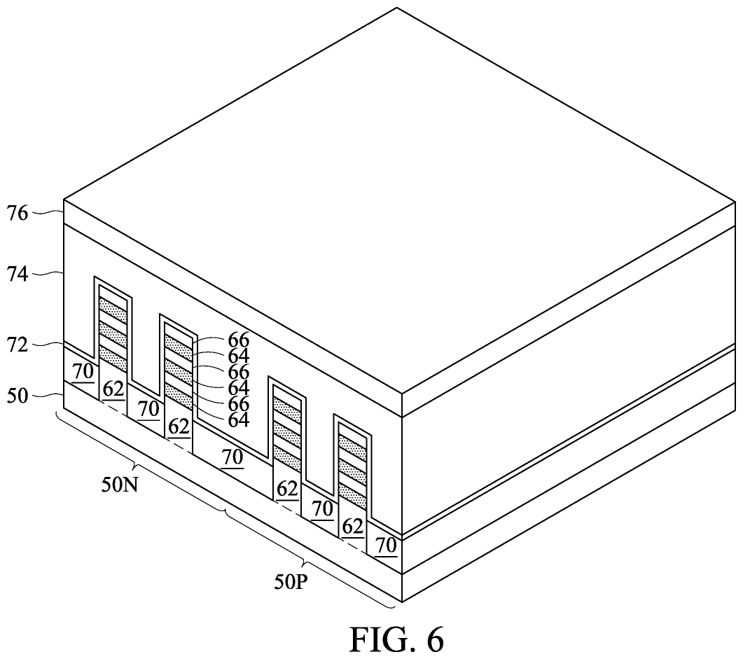

In FIG. 6, a dummy dielectric layer 72 is formed on the fins 62 and/or the nanostructures 64/66. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The dummy gate layer 74 may be formed of a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be formed of other materials that have a high etching selectivity from the etching of insulation materials, e.g., the STI regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the STI regions 70, such that the dummy dielectric layer 72 extends between the dummy gate layer 74 and the STI regions 70. In another embodiment, the dummy dielectric layer 72 covers only the fins 62 and/or the nanostructures 64/66.

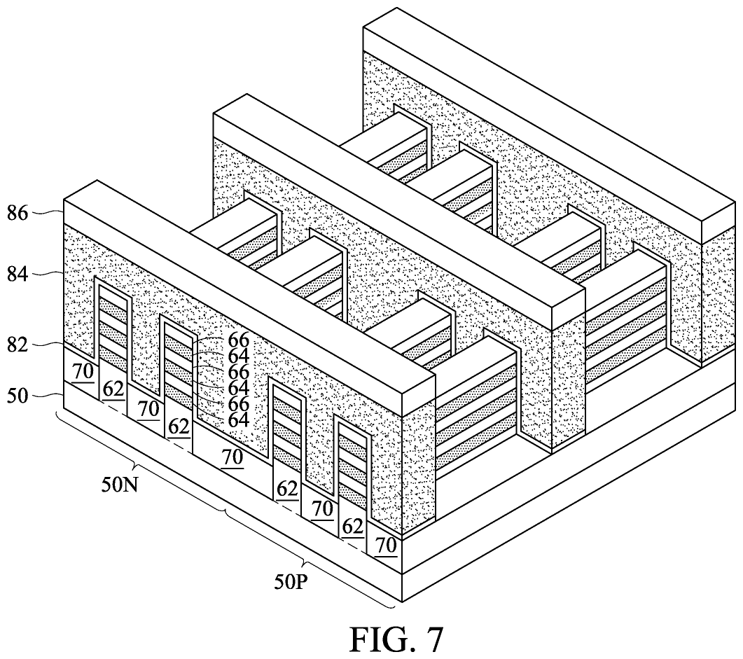

In FIG. 7, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

FIGS. 8-16C illustrate various additional steps in the manufacturing of embodiment devices. FIGS. 8-13C and 15A-16C illustrate features in either of the n-type region 50N and the p-type region 50P. For example, the structures illustrated may be applicable to both the n-type region 50N and the p-type region 50P. Differences (if any) in the structures of the n-type region 50N and the p-type region 50P are explained in the description of each figure.

In FIGS. 8A-8C, a spacer layer 90 is conformally formed over the nanostructures 64/66 and the STI regions 70, on exposed sidewalls of the masks 86 (if present), the dummy gates 84, the dummy dielectrics 82, the nanostructures 64/66, and the fins 62. The spacer layer 90 may be formed of one or more dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 will be subsequently etched to form spacers. In some embodiments, the spacer layer 90 (and the subsequently formed gate spacers 92 and/or fin spacers 94) may be formed of two or more layers of different materials.

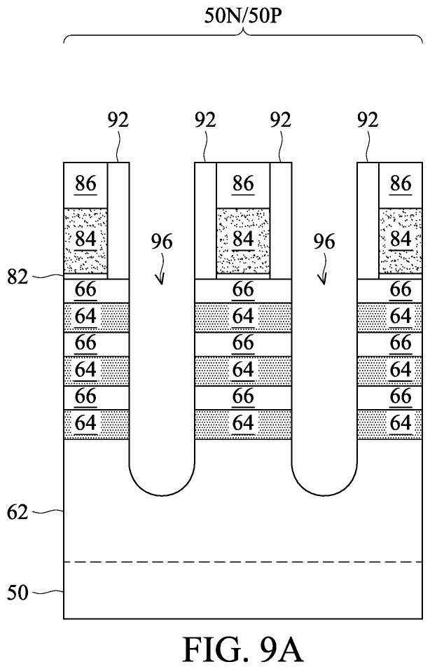

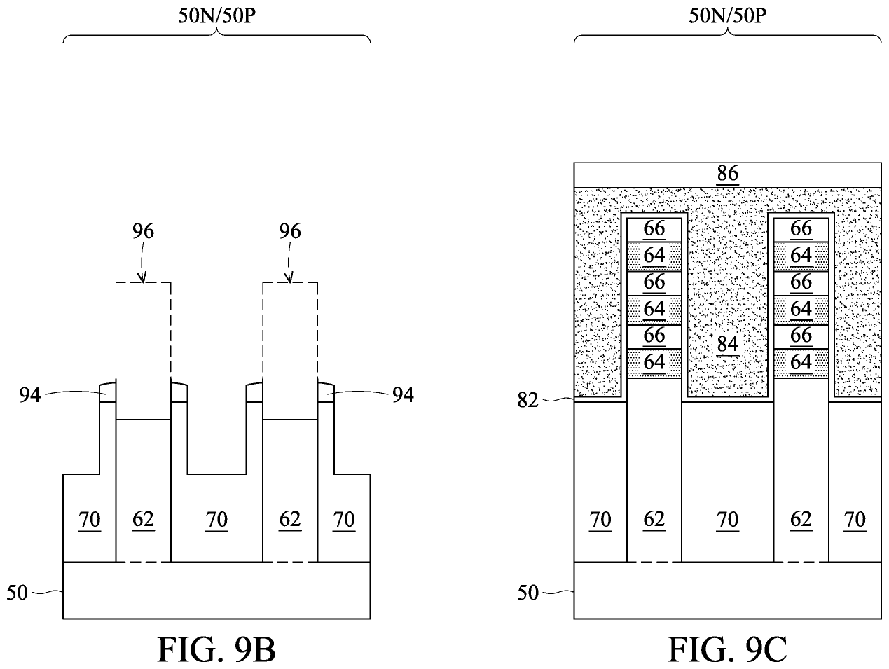

In FIGS. 9A-9C, the spacer layer 90 is patterned to form gate spacers 92 and fin spacers 94. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. Additionally, the STI regions 70 may also be etched when patterning the spacer layer 90. The etching may recess portions of the STI regions 70 between the fins 62.

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 9A-9C, source/drain recesses 96 are formed in the fins 62, the nanostructures 64/66, and the substrate 50, in accordance with some embodiments. Epitaxial source/drain regions will be subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are disposed below the top surfaces of the STI regions 70. The source/drain recesses 96 may be formed by etching the fins 62, the nanostructures 64/66, and the substrate 50 using anisotropic etching processes, such as RIE, NBE, or the like. The gate spacers 92 and the dummy gates 84 mask portions of the fins 62, the nanostructures 64/66, and the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth.

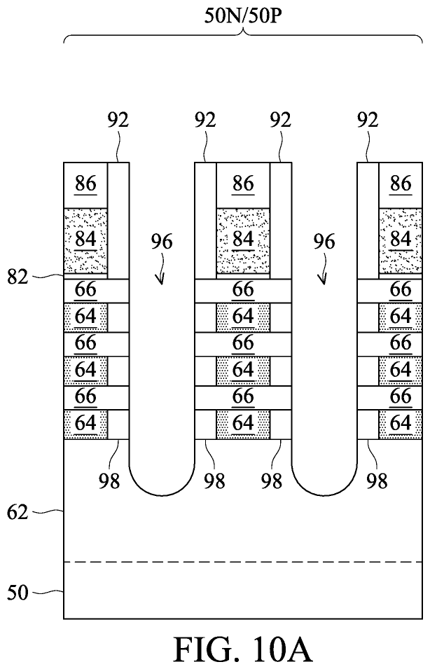

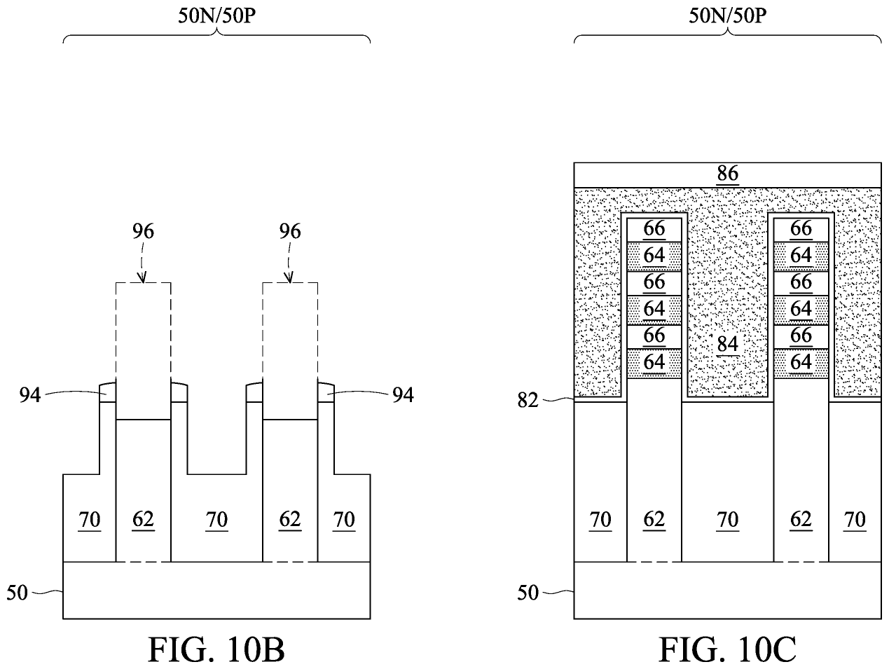

In FIGS. 10A-10C, inner spacers 98 are formed on the sidewalls of the remaining portions of the first nanostructures 64, e.g., those sidewalls exposed by the source/drain recesses 96. As will be subsequently described in greater detail, source/drain regions will be subsequently formed in the source/drain recesses 96, and the first nanostructures 64 will be subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to subsequently remove the first nanostructures 64.

As an example to form the inner spacers 98, the source/drain recesses 96 can be laterally expanded. Specifically, portions of the sidewalls of the first nanostructures 64 exposed by the source/drain recesses 96 may be recessed to form sidewall recesses. Although sidewalls of the first nanostructures 64 are illustrated as being straight, the sidewalls may be concave or convex. The sidewalls may be recessed by any acceptable etch process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some embodiments, the same etch process may be continually performed to both form the source/drain recesses 96 and recess the sidewalls of the first nanostructures 64. The inner spacers 98 can then be formed by conformally forming an insulating material in the source/drain recesses 96, and subsequently etching the insulating material. The insulating material may be silicon nitride or silicon oxynitride, although any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like.

Although outer sidewalls of inner spacers 98 are illustrated as being flush (e.g., coterminous) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses. Moreover, although the sidewalls of the inner spacers 98 are illustrated as being straight, the sidewalls of the inner spacers 98 may be concave or convex.

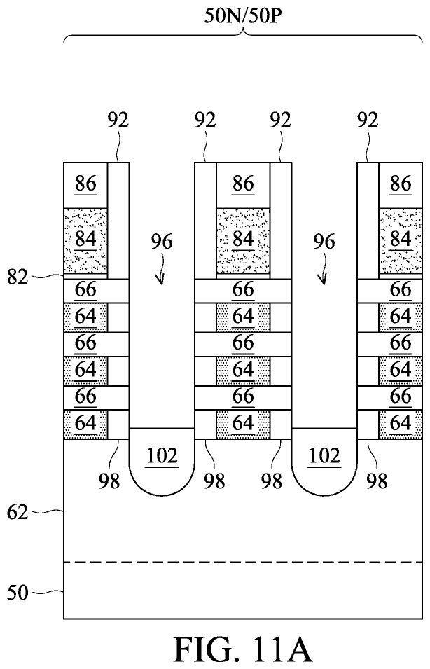

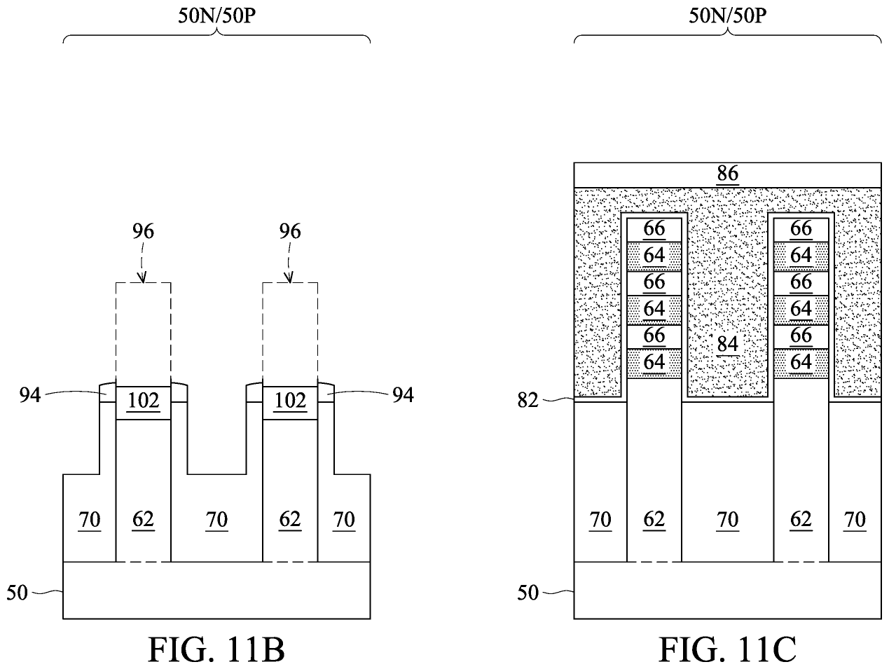

In FIGS. 11A-11C, semiconductor layers 102 are formed in the source/drain recesses 96, in accordance with some embodiments. The semiconductor layers 102 may be formed of a semiconductor material selected from the candidate semiconductor materials of the substrate 50, which may be grown by an epitaxial growth process such as vapor phase epitaxy (VPE), molecular beam epitaxy (MBE), or the like. The semiconductor layers 102 may be undoped semiconductor layers. In some embodiments, the semiconductor layers 102 are formed of undoped silicon or undoped silicon germanium. In this embodiment, the top surfaces of the semiconductor layers 102 are flat. In other embodiments, the top surfaces of the semiconductor layers 102 are convex or concave.

The semiconductor layers 102 may be epitaxially grown, for example, by flowing a semiconductor-containing precursor and an etchant-containing precursor into the source/drain recesses 96. The semiconductor-containing precursor may be a silicon-containing precursor such as a silane, such as monosilane (SiH₄), dichlorosilane (H₂SiCl₂), disilane (Si₂H₆), or the like; a germanium-containing precursor such as germane (GeH₄) or the like; combinations thereof; or the like. The etchant-containing precursor may be a chlorine-containing precursor such as hydrogen chloride (HCl) gas, chlorine (Cl₂) gas, or the like. The etchant-containing precursor is flowed at a relatively fast flow rate, which may cause the semiconductor layers 102 to be grown in more of a bottom-up manner than a lateral manner. In some embodiments, the semiconductor-containing precursor is flowed at a flow rate in the range of about 0 sccm to about 1000 sccm and the etchant-containing precursor is flowed at a flow rate in the range of about 0 sccm to about 1000 sccm. As such, the semiconductor layers 102 may be grown from the fins 62 but not from the nanostructures 66. In some embodiments, the epitaxial growth is performed at a temperature in the range of about 500° C. to about 900° C., and at a pressure in the range of about 1 Torr to about 150 Torr. The semiconductor layers 102 may be formed with flat, convex, or concave top surfaces by controlling the flow rate of the etchant-containing precursor during deposition. The semiconductor layers 102 may partially fill, completely fill, or overfill the portions of the source/drain recesses 96 in the fins 62. At this step of processing, the semiconductor layers 102 may be in contact with the sidewalls of some of the inner spacers 98, but the semiconductor layers 102 are not in contact with the sidewalls of the nanostructures 66. Timed epitaxial growth processes may be used to stop the growth of the semiconductor layers 102 after the semiconductor layers 102 reach a desired height.

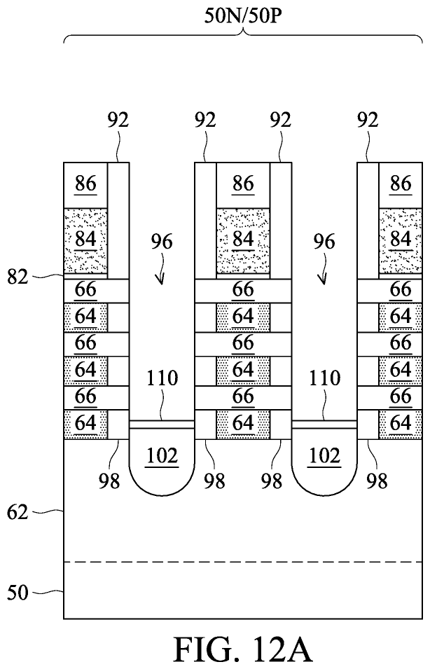

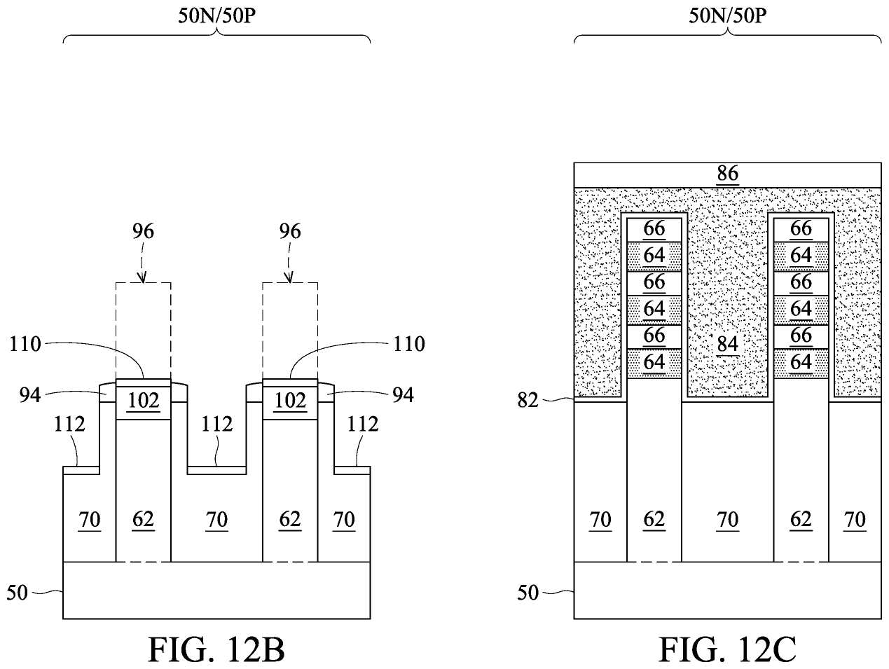

In FIGS. 12A-12C, bottom spacers 110 are formed on the semiconductor layers 102, in accordance with some embodiments. Additionally, bottom spacers 112 may also be formed on other horizontal surfaces, such as on portions of the STI regions 70 between the source/drain recesses 96. In some embodiments where the semiconductor layers 102 are not in contact with the sidewalls of the nanostructures 66, the bottom spacers 110 are disposed beneath the top surfaces of the lower inner spacers 98 (e.g., the inner spacers 98 disposed closest to the substrate 50). In other embodiments, the bottom spacers 110 may be disposed above the top surfaces of the lower inner spacers 98. The bottom spacers 110/112 may be formed by conformally forming one or more dielectric material(s) over the semiconductor layers 102, the fin spacers 94, the gate spacers 92, the STI regions 70, and the masks 86 (if present) or the dummy gates 84, and then subsequently etching the dielectric material(s). Acceptable dielectric materials may include silicon nitride, silicon oxynitride, silicon oxycarbonitride, silicon oxycarbide, silicon carbonitride, silicon oxide, aluminum oxide, hafnium oxide, or the like, which may be formed by a deposition process such as chemical vapor deposition (CVD), atomic layer deposition (ALD), or the like. Any acceptable etch process, such as a dry etch, a wet etch, the like, or a combination thereof, may be performed to pattern the dielectric material(s). The etching may be anisotropic. The etching removes the vertical portions of the dielectric material(s). The dielectric material(s), when etched, have horizontal portions left on the top surfaces of the STI regions 70 and/or the semiconductor layers 102 (thus forming the bottom spacers 112 and/or the bottom spacers 110). The bottom spacers 110 may be thin, so as to not occupy excessive space in the source/drain recesses 96. In some embodiments, a thickness of the bottom spacers 110 is in the range of 3 nm to 5 nm. Other thicknesses are possible.

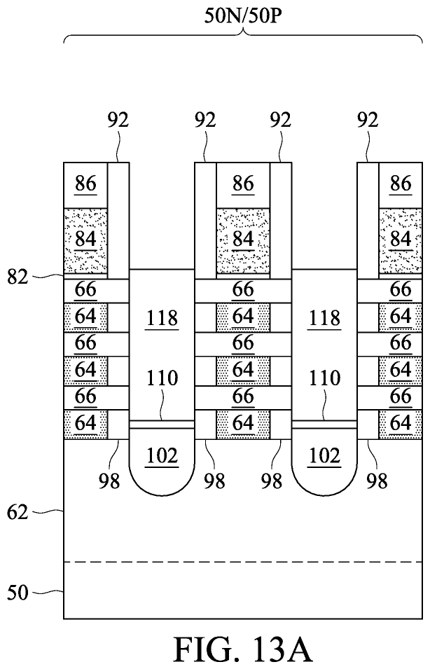

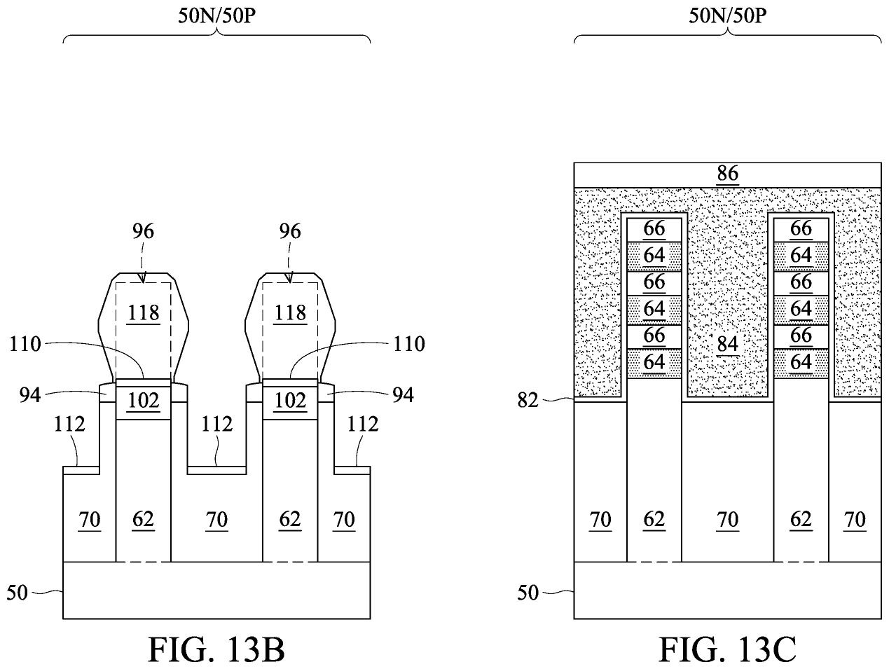

In FIGS. 13A-13C, epitaxial source/drain regions 118 are formed in the source/drain recesses 96. In some embodiments, the epitaxial source/drain regions 118 exert stress in the respective channel regions of the second nanostructures 66, thereby improving performance. The epitaxial source/drain regions 118 are formed in the source/drain recesses 96 such that each dummy gate 84 is disposed between respective neighboring pairs of the epitaxial source/drain regions 118. In some embodiments, the gate spacers 92 are used to separate the epitaxial source/drain regions 118 from the dummy gates 84 and the inner spacers 98 are used to separate the epitaxial source/drain regions 118 from the nanostructures 64 by an appropriate lateral distance so that the epitaxial source/drain regions 118 do not short out with subsequently formed gates of the resulting nanostructure-FETs. The epitaxial source/drain regions 118 extend above the top surface of the nanostructures 66. As a result, the top surface of an epitaxial source/drain region 118 is disposed further from the substrate 50 than the top surface of the adjacent nanostructures 66.

The epitaxial source/drain regions 118 in the n-type region 50N may be formed by an epitaxy process (subsequently described). The epitaxial source/drain regions 118 may include any acceptable material appropriate for n-type nanostructure-FETs. For example, if the second nanostructures 66 are formed of silicon, the epitaxial source/drain regions 118 may include materials exerting a tensile strain on the second nanostructures 66, such as silicon, silicon carbide, phosphorous doped silicon carbide, silicon phosphide, or the like. The epitaxial source/drain regions 118 in the n-type region 50N may be referred to as “n-type source/drain regions.” The epitaxial source/drain regions 118 may have surfaces raised from respective upper surfaces of the nanostructures 64/66, may have facets, and may have a different shape than shown in FIGS. 13A-13B.

The epitaxial source/drain regions 118 in the p-type region 50P may be formed by an epitaxy process (subsequently described). The epitaxial source/drain regions 118 may include any acceptable material appropriate for p-type nanostructure-FETs. For example, if the second nanostructures 66 are formed of silicon, the epitaxial source/drain regions 118 may comprise materials exerting a compressive strain on the first nanostructures 64, such as silicon-germanium, boron doped silicon-germanium, germanium, germanium tin, or the like. The epitaxial source/drain regions 118 in the p-type region 50P may be referred to as “p-type source/drain regions.” The epitaxial source/drain regions 118 may also have surfaces raised from respective surfaces of the nanostructures 64/66, may have facets, and may have a different shape than shown in FIGS. 13A-13B.

The epitaxial source/drain regions 118, the nanostructures 64/66, and/or the fins 62 may be implanted with dopants to form source/drain regions, similar to the process previously discussed for forming lightly-doped source/drain regions, followed by an anneal. The source/drain regions may have an impurity concentration of between 10¹⁹ atoms/cm³ and 10²¹ atoms/cm³. The n-type and/or p-type impurities for source/drain regions may be any of the impurities previously discussed. In some embodiments, the epitaxial source/drain regions 118 may be in situ doped during growth.

As a result of the epitaxy processes used to form the epitaxial source/drain regions 118, upper surfaces of the epitaxial source/drain regions 118 have facets which expand laterally outward beyond sidewalls of the nanostructures 64/66. In some embodiments, these facets cause adjacent epitaxial source/drain regions 118 of a same nanostructure-FET to merge. In other embodiments, adjacent epitaxial source/drain regions 118 remain separated after the epitaxy process is completed, as illustrated by FIG. 13B. In the illustrated embodiments, the fin spacers 94 are formed on top surfaces of the STI regions 70, thereby blocking the epitaxial growth. In some other embodiments, the fin spacers 94 may cover portions of the sidewalls of the nanostructures 64/66 and/or the fins 62, further blocking the epitaxial growth. In another embodiment, the spacer etch used to form the gate spacers 92 is adjusted to not form the fin spacers 94, so as to allow the epitaxial source/drain regions 118 to extend to the surface of the STI region 70.

The bottom spacers 110 cover the semiconductor layers 102 such that the epitaxial source/drain regions 118 are not grown from the semiconductor layers 102. Accordingly, the epitaxial source/drain regions 118 are electrically isolated from the semiconductor layers 102. The semiconductor layers 102 and the bottom spacers 110 are beneath the epitaxial source/drain regions 118. The bottom spacers 110 are between the semiconductor layers 102 and the epitaxial source/drain regions 118.

In some embodiments, the epitaxial source/drain regions 118 in the n-type region 50N and in the p-type region 50P may be formed simultaneously. In other embodiments, the epitaxial source/drain regions 118 in the n-type region 50N and in the p-type region 50P may be formed sequentially. For example, in some embodiments, a mask (not shown) may be formed that covers the p-type region 50P while the epitaxial source/drain regions 118 are formed in the n-type region 50N. Similarly another mask (not shown) may be formed that covers the n-type region 50N while the epitaxial source/drain regions 118 are formed in the p-type region 50P. Each mask may be formed of a hard mask material, such as aluminum oxide, silicon carbide, titanium nitride, or the like, which may be formed by a deposition process such as chemical vapor deposition (CVD), atomic layer deposition (ALD), or the like. Each mask can be patterned using acceptable photolithography and etching techniques to expose the source/drain recesses 96 in the n-type region 50N or the p-type region 50P as appropriate. In other embodiments, another type of mask, such as a photoresist, may be utilized. After growth of the epitaxial source/drain regions 118 in the n-type region 50N or the p-type region 50P, the mask may be removed with any acceptable etch process that is selective to the mask (e.g., selectively etches the material of the mask at a faster rate than the material of the epitaxial source/drain regions 118). The etch process may be isotropic. For example, when the mask is formed of aluminum oxide, the etch process may be a wet etch using ammonium hydroxide (NH₄OH), dilute hydrofluoric (dHF) acid, or the like.

In some embodiments, the epitaxial source/drain regions 118 are epitaxially grown in the source/drain recesses 96 in the n-type region 50N while a mask substantially prevents growth in the p-type region 50P. The epitaxy processes used to form the epitaxial source/drain regions 118 are performed so that the epitaxial source/drain regions 118 are selectively grown from semiconductor features (e.g., the nanostructures 66) and do not grow from dielectric features (e.g., the bottom spacers 110). The epitaxial source/drain regions 118 may be grown by flowing a semiconductor-containing precursor, an etchant-containing precursor, and a dopant-containing precursor in the source/drain recesses 96. The semiconductor-containing precursor and the etchant-containing precursor may be selected from, respectively, the same semiconductor-containing precursors and etchant-containing precursors for growing the semiconductor layers 102, or may include different precursors. The dopant-containing precursor contains an appropriate dopant for n-type source/drain regions, such as an arsenic-containing precursor such as arsine (AsH₃), a phosphorus-containing precursor such as diphosphine (P₂H₆) or phosphane (PH₃), or the like. The etchant-containing precursor may be flowed at a slower flow rate when growing the epitaxial source/drain regions 118 than when growing the semiconductor layers 102, which may cause the epitaxial source/drain regions 118 to be grown in more of a lateral manner than a bottom-up manner. In some embodiments, the semiconductor-containing precursor is flowed at a flow rate in the range of 0 sccm to 1000 sccm, the etchant-containing precursor is flowed at a flow rate in the range of 0 sccm to 1000 sccm, and the dopant-containing precursor is flowed at a flow rate in the range of 0 sccm to 1000 sccm. The epitaxy process for the epitaxial source/drain regions 118 may have a faster lateral growth rate and a slower bottom-up growth rate than the epitaxy process for the semiconductor layers 102. As such, the epitaxial source/drain regions 118 may grow laterally from the nanostructures 66. In some embodiments, the epitaxial growth is performed at a temperature in the range of 400° C. to 900° C., and at a pressure in the range of 1 Torr to 500 Torr.

In some embodiments, the epitaxial source/drain regions 118 are epitaxially grown in the source/drain recesses 96 in the p-type region 50P while a mask substantially prevents growth in the n-type region 50N. The epitaxy processes used to form the epitaxial source/drain regions 118 are performed so that the epitaxial source/drain regions 118 are selectively grown from semiconductor features (e.g., the nanostructures 66) and do not grow from dielectric features (e.g., the bottom spacers 110). The epitaxial source/drain regions 118 may be grown by flowing a semiconductor-containing precursor, an etchant-containing precursor, and a dopant-containing precursor in the source/drain recesses 96. The semiconductor-containing precursor and the etchant-containing precursor may be selected from, respectively, the same semiconductor-containing precursors and etchant-containing precursors for growing the semiconductor layers 102, or may include different precursors. The dopant-containing precursor contains an appropriate dopant for p-type source/drain regions, such as a boron-containing precursor, such as diborane (B₂H₆), borane (BH₃), or the like. The etchant-containing precursor may be flowed at a slower flow rate when growing the epitaxial source/drain regions 118 than when growing the semiconductor layers 102, which may cause the epitaxial source/drain regions 118 to be grown in more of a lateral manner than a bottom-up manner. In some embodiments, the semiconductor-containing precursor is flowed at a flow rate in the range of 0 sccm to 1000 sccm, the etchant-containing precursor is flowed at a flow rate in the range of 0 sccm to 1000 sccm, and the dopant-containing precursor is flowed at a flow rate in the range of 0 sccm to 1000 sccm. The epitaxy process for the epitaxial source/drain regions 118 may have a faster lateral growth rate and a slower bottom-up growth rate than the epitaxy process for the semiconductor layers 102. As such, the epitaxial source/drain regions 118 may grow laterally from the nanostructures 66. In some embodiments, the epitaxial growth is performed at a temperature in the range of 400° C. to 900° C., and at a pressure in the range of 1 Torr to 150 Torr.

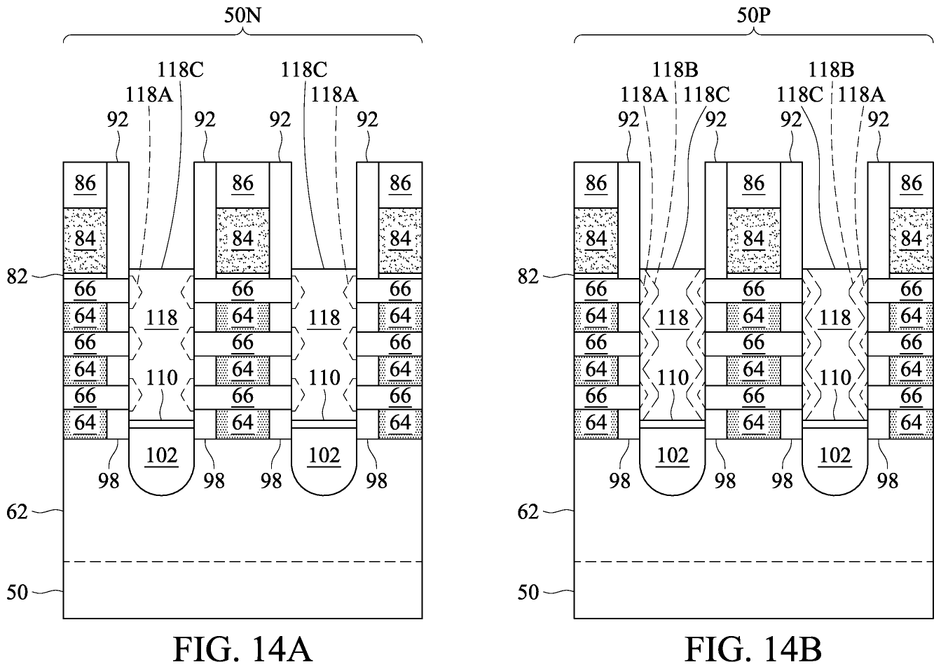

The epitaxial source/drain regions 118 may comprise one or more semiconductor material layers. For example, the epitaxial source/drain regions 118 may comprise a liner layer, a main layer, and a finishing layer (or more generally, a first semiconductor material layer, a second semiconductor material layer, and a third semiconductor material layer). Each of the liner layer, the main layer, and the finishing layer may be formed of different semiconductor materials and may be doped to different dopant concentrations. In some embodiments, the liner layer may have a dopant concentration less than the main layer and greater than the finishing layer. In embodiments in which the epitaxial source/drain regions 118 include three semiconductor material layers, the liner layers may be grown in the source/drain recesses 96, the main layers may be grown on the liner layers, and the finishing layers may be grown on the main layers. Any number of semiconductor material layers may be used for the epitaxial source/drain regions 118. In some embodiments, the epitaxial source/drain regions 118 in the n-type region 50N include liner layers 118A on the nanostructures 66 and fill layers 118C on the liner layers 118A, as demonstrated in FIG. 14A. In some embodiments, the epitaxial source/drain regions 118 in the p-type region 50P include liner layers 118A on the nanostructures 66, liner layers 118B on the liner layers 118A, and fill layers 118C on the liner layers 118B, as demonstrated in FIG. 14B.

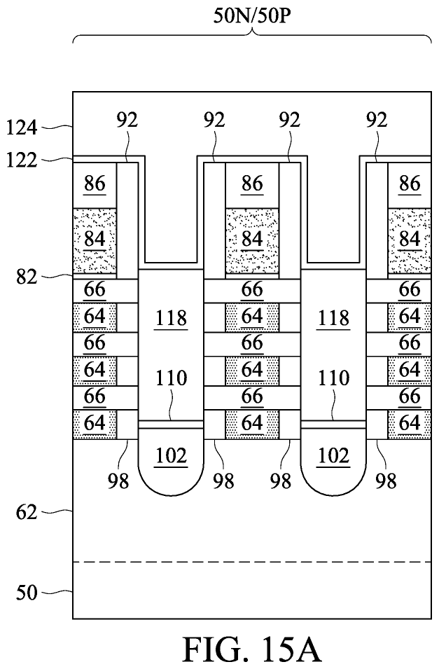

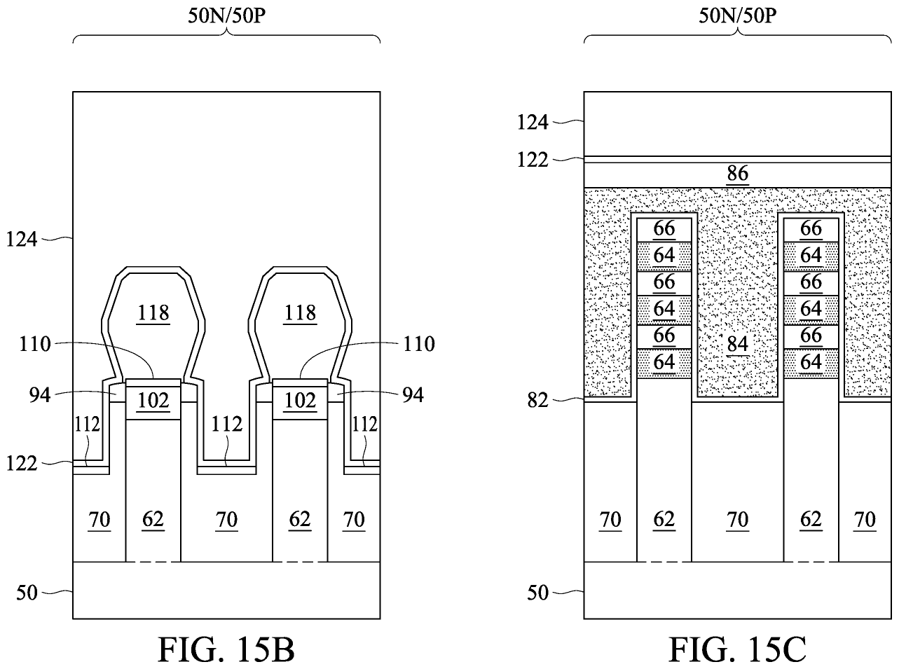

In FIGS. 15A-15C, a first ILD 124 is deposited over the epitaxial source/drain regions 118, the bottom spacers 112, the fin spacers 94, the gate spacers 92, and the masks 86 (if present) or the dummy gates 84. The first ILD 124 may be formed of a dielectric material, which may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 122 is formed between the first ILD 124 and the epitaxial source/drain regions 118, the bottom spacers 112, the fin spacers 94, the gate spacers 92, and the masks 86 (if present) or the dummy gates 84. The CESL 122 may be formed of a dielectric material having a high etching selectivity from the etching of the first ILD 124, such as, silicon nitride, silicon oxide, silicon oxynitride, or the like, which may be formed by any suitable deposition process, such as CVD, ALD, or the like.

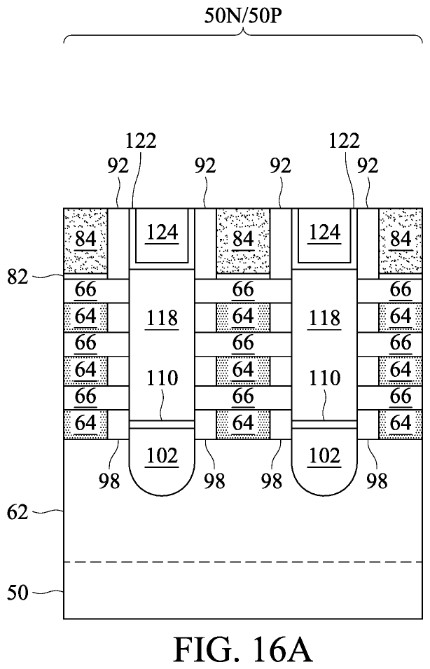

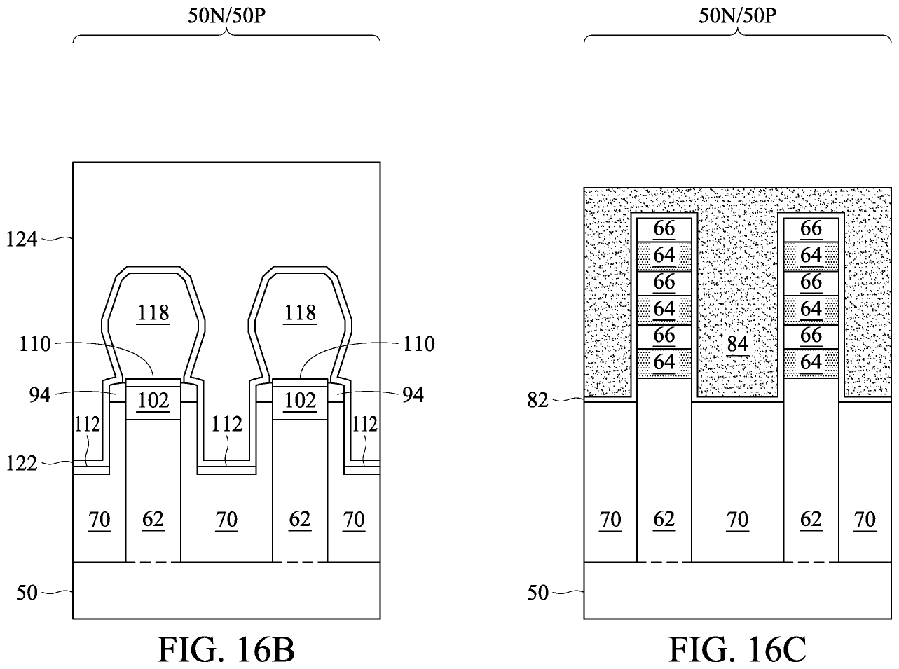

In FIGS. 16A-16C, a removal process is performed to level the top surfaces of the first ILD 124 with the top surfaces of the gate spacers 92 and the dummy gates 84. In some embodiments, a planarization process such as a chemical mechanical polish (CMP), an etch-back process, combinations thereof, or the like may be utilized. The planarization process removes the masks 86 on the dummy gates 84, and removes portions of the gate spacers 92 along sidewalls of the masks 86 and/or the dummy gates 84. After the planarization process, top surfaces of the first ILD 124, the gate spacers 92 and the dummy gates 84 are substantially coplanar (within process variations). Accordingly, the top surfaces of the dummy gates 84 are exposed through the first ILD 124. In other embodiments, portions of the masks 86 are remain after performing the planarization process.

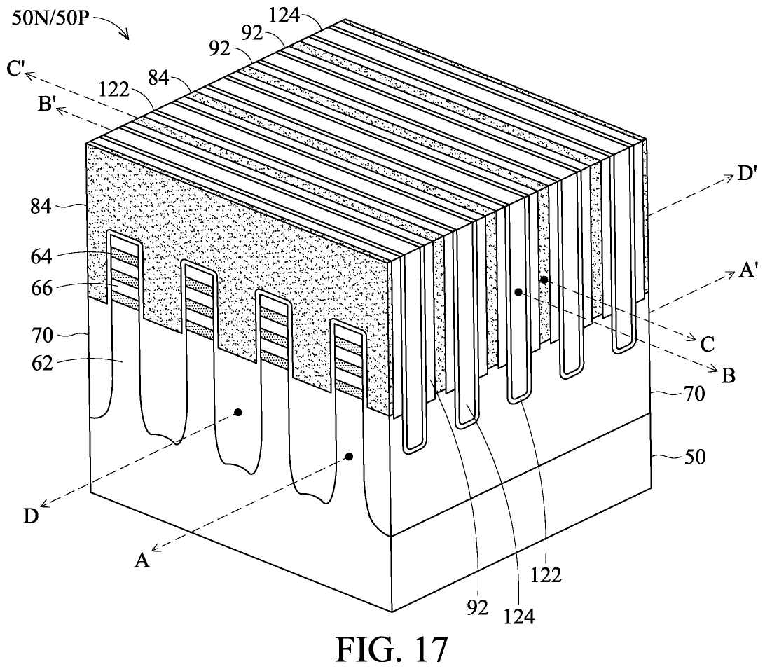

FIGS. 17 through 31B illustrate various additional steps in the manufacturing of embodiment devices. FIG. 17-31B illustrate features in either of the n-type region 50N and the p-type region 50P. For example, the structures illustrated may be applicable to both the n-type region 50N and the p-type region 50P. Differences (if any) in the structures of the n-type region 50N and the p-type region 50P are explained in the description of each figure. Note that some features illustrated in FIGS. 17-31B may be shown as having different shapes or sizes than the corresponding features in FIGS. 1-16C.

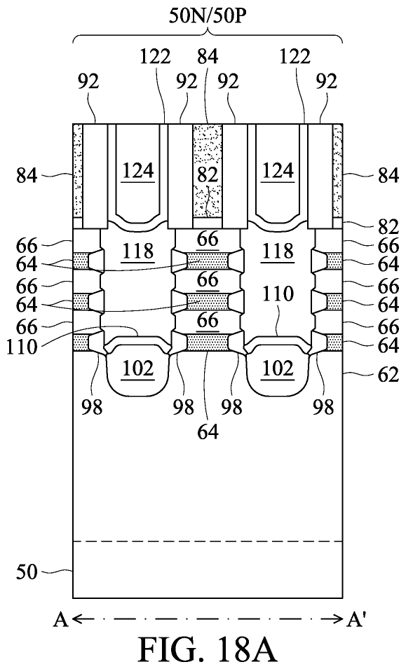

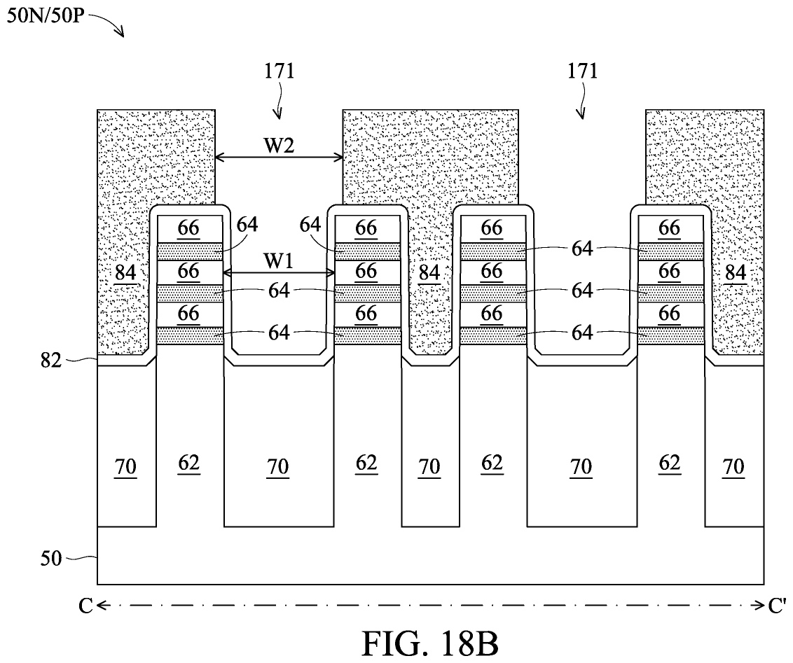

FIG. 17 illustrates a three-dimensional view of the structure after performing the planarization process described previously for FIGS. 16A-16C, in accordance with some embodiments. For clarity, each cross-sectional view of FIGS. 18-31B is labeled with its corresponding reference cross-section (e.g., A-A′, B-B′, C-C′, or D-D′) to which it is similar. Example reference cross-sections are shown in FIG. 17, each of which corresponds to a similar reference cross-section shown in FIG. 1.

In FIGS. 18A and 18B, portions of the dummy gates 84 are removed in one or more etching steps, so that recesses 171 are formed between nanostructures 64/66, in accordance with some embodiments. The recesses 171 may be formed using acceptable photolithography and etching techniques. For example, a patterned mask may be formed over the dummy gates 84 in which the pattern corresponds to the recesses 171. The dummy gates 84 may then be etched using the patterned mask as an etching mask. The etching may comprise a wet etching process and/or a dry etching process, which may be anisotropic. In some cases, the etching may be selective to the material of the dummy gates 84 such that the dummy dielectrics 82 acts as an etch stop layer. In this manner, the recesses 171 may expose the dummy dielectrics 82. In some embodiments, the recesses 171 may have an upper width W2 that is greater than the width W1 between the adjacent nanostructures 64/66, as shown in FIG. 18B. For example, in some embodiments, the recesses 171 may extend over top surfaces of the adjacent nanostructures 64/66, and may expose top surfaces of the dummy dielectrics 82 over the nanostructures 64/66. In some embodiments, the upper width W2 may be in the range of about 25 nm to about 60 nm, though other widths are possible. In other embodiments, the upper width W2 may be about the same as or smaller than the width W1. In some embodiments, different recesses 171 may have different widths W1 and/or different upper widths W2.

In FIG. 19, a liner layer 172 and a dielectric material 174 are deposited into the recesses 171, in accordance with some embodiments. The liner layer 172 is an optional layer that is conformally deposited on the dummy gates 84 and within the recesses 171. For example, the liner layer 172 may be deposited on exposed surfaces of the dummy gates 84 and the dummy dielectrics 82 within the recesses 171. The liner layer 172 is formed of a dielectric material that can be selectively etched in a subsequent removal process. Acceptable dielectric materials may include aluminum oxide, aluminum nitride, silicon oxide, silicon nitride, silicon carbonitride, silicon oxycarbonitride, or the like, which may be formed by a deposition process such as chemical vapor deposition (CVD), atomic layer deposition (ALD), or the like. In some embodiments, the liner layer 172 is a material similar to that of the dummy dielectrics 82. Other materials or deposition techniques are possible. In some embodiments, the liner layer 172 has a thickness in the range of 1 nm to 6 nm, though other thicknesses are possible. In other embodiments, the liner layer 172 is not present.

The dielectric material 174 is then deposited, filling the recesses 171. For example, the dielectric material 174 may be deposited on surfaces of the liner layer 172. The dielectric material 174 may include one or more acceptable dielectric materials such as silicon oxide, silicon nitride, silicon oxynitride, silicon oxycarbonitride, or the like, which may be formed by a deposition process such as CVD, ALD, or the like. In some embodiments, the dielectric material 174 is a different material than the liner layer 172. Other materials or deposition techniques are possible. A distance W3 between the dielectric material 174 and an adjacent nanostructure 66 may be defined by the combined thickness of the dummy dielectrics 82 and the liner layer 172. In some embodiments, the distance W3 is in the range of about 4 nm to about 10 nm, though other distances are possible. In some cases, the distance W3 may be approximately equal to an “end-cap” distance of subsequently formed gate electrodes, described below. In some embodiments, a planarization process (e.g., a CMP process and/or a grinding process) is performed to remove excess liner layer 172 and dielectric material 174 from top surfaces of the dummy gates 84. In some embodiments, the formation of the dielectric material 174 (and, correspondingly, the dielectric walls) may be considered a self-aligned process.

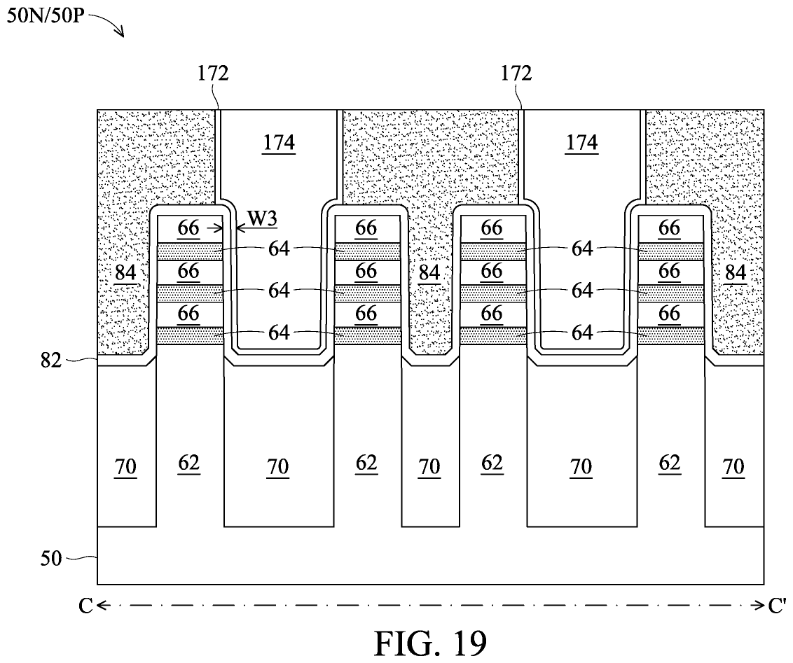

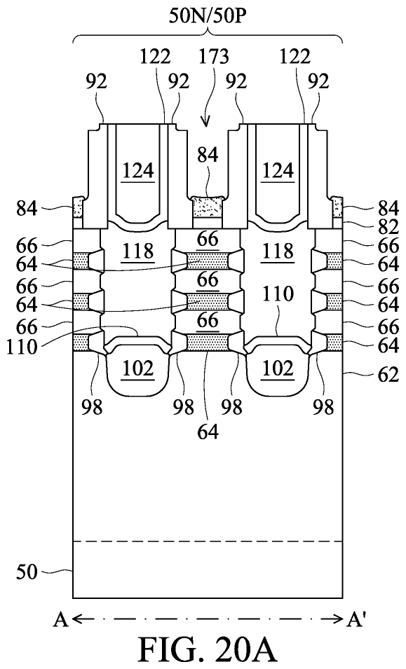

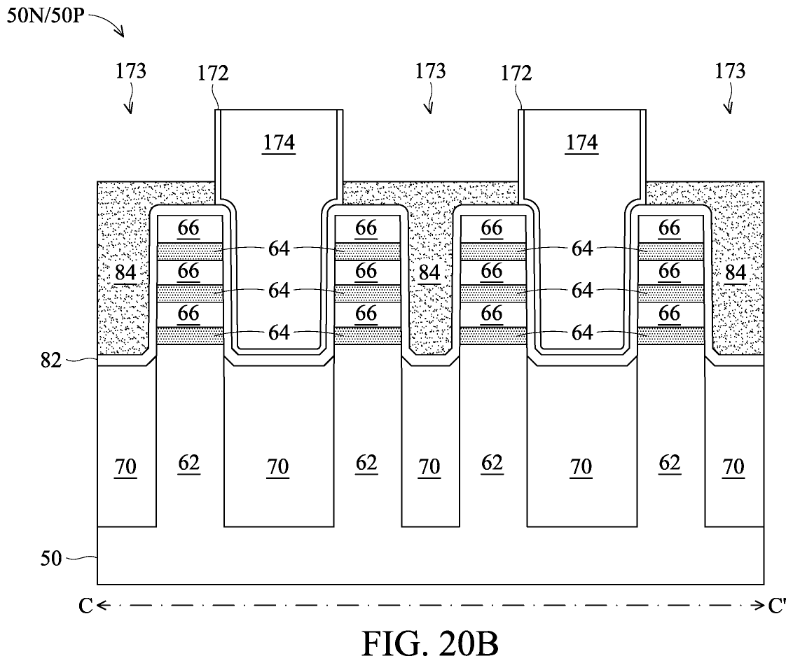

In FIGS. 20A and 20B, portions of the dummy gates 84 are recessed in one or more etching steps, so that recesses 173 are formed between dielectric walls (e.g., between dielectric material 174) and between gate spacers 92, in accordance with some embodiments. The one or more etching steps may include a wet etching process and/or a dry etching process, which may be anisotropic. In some cases, the etching may be selective to the material of the dummy gates 84 such that the material of the dummy gates 84 is etched at a greater rate than the materials of the liner layer 172, the dielectric material 174, and/or the gate spacers 92. The recessing may be performed using a timed etching process, in some cases.

In some embodiments, sidewall portions of the gate spacers 92 are trimmed in one or more etching steps, as shown in FIG. 20A. The gate spacers 92 may be trimmed after the recessing of the dummy gates 84. The trimming may etch sidewalls of the gate spacers 92, such that sidewall portions of the gate spacers 92 exposed by the recesses 173 are thinner than sidewall portions of the gate spacers 92 that are still covered by the dummy gates 84 and/or the dummy dielectrics 82. In other words, the trimming increases the width of the recesses 173 between gate spacers 92. The one or more etching steps may include a wet etching process and/or a dry etching process, which may be anisotropic. In some cases, the etching may be selective to the material of the gate spacers 92 such that the material of the gate spacers 92 is etched at a greater rate than the materials of the liner layer 172, the dielectric material 174, and/or the dummy gates 84. In other embodiments, the gate spacers 92 are trimmed by one or more of the same etching steps that recess the dummy gates 84.

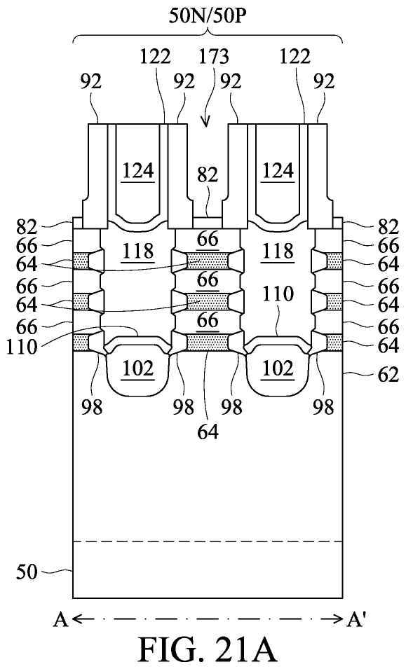

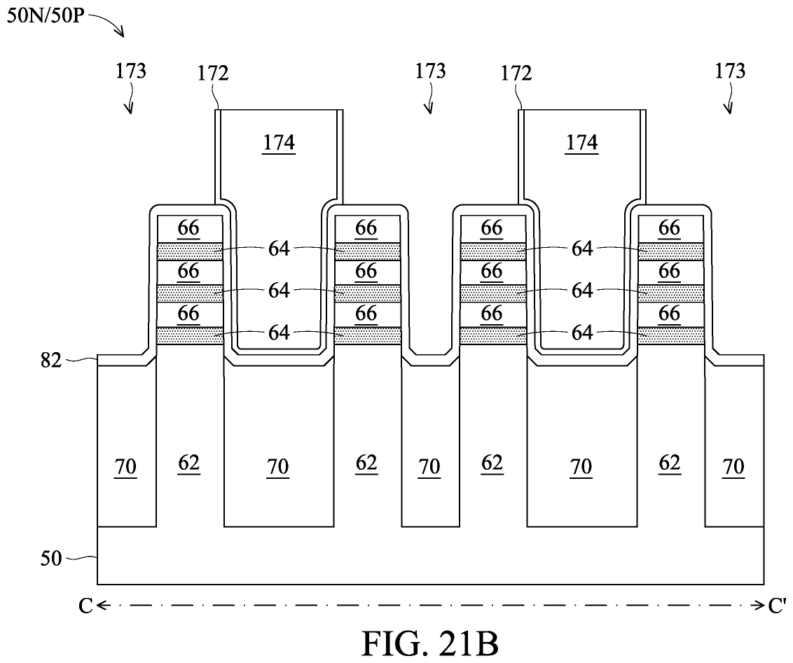

In FIGS. 21A-21B, the remaining portions of the dummy gates 84 are removed, in accordance with some embodiments. The dummy gates 84 may be removed using one or more etching steps, which may include a wet etching process and/or a dry etching process. The etching step(s) may be similar to the etching step(s) described for FIGS. 18A-18B or FIGS. 20A-20B. In some embodiments, the etching is selective to the material of the dummy gates 84 such that the etching stops or slows on the liner layer 172 and/or the dummy dielectrics 82. As shown in FIG. 21B, removing the dummy gates 84 extends the recesses 173 between some adjacent nanostructures 64/66.

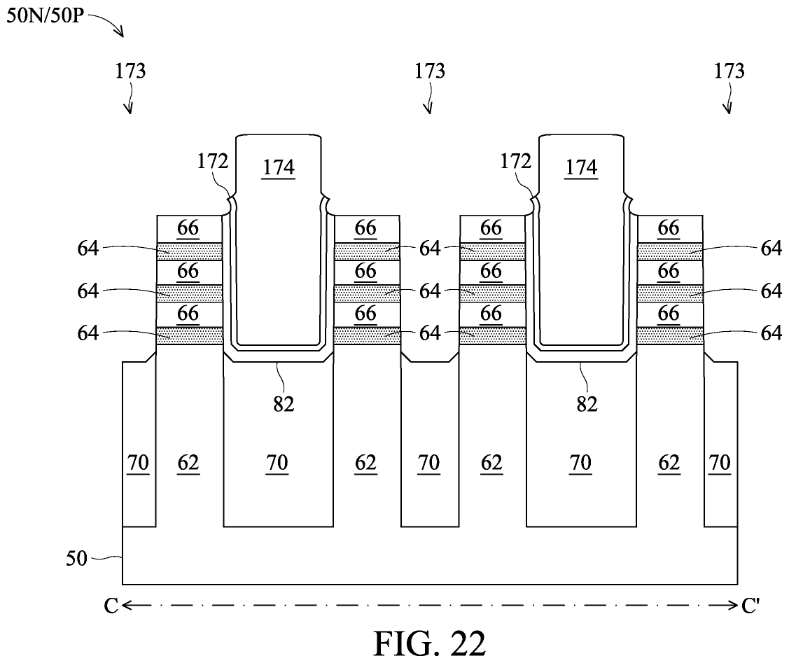

In FIG. 22, one or more etching steps are performed to remove exposed portions of the dummy dielectrics 82 and the liner layer 172, in accordance with some embodiments. As shown in FIG. 22, some portions of the dummy dielectrics 82 and liner layer 172 may remain after the etching. The one or more etching steps may include a wet etching process and/or a dry etching process, which may be isotropic or anisotropic. In some cases, the etching may be selective to the material of the dummy dielectrics 82 and/or the liner layer 172 such that the materials of the dummy dielectrics 82 and/or the liner layer 172 are etched at a greater rate than the materials of the isolation regions 70 and/or the nanostructures 64/66. As shown in FIG. 22, the etching may also etch (e.g., “trim”) upper portions of the dielectric material 174.

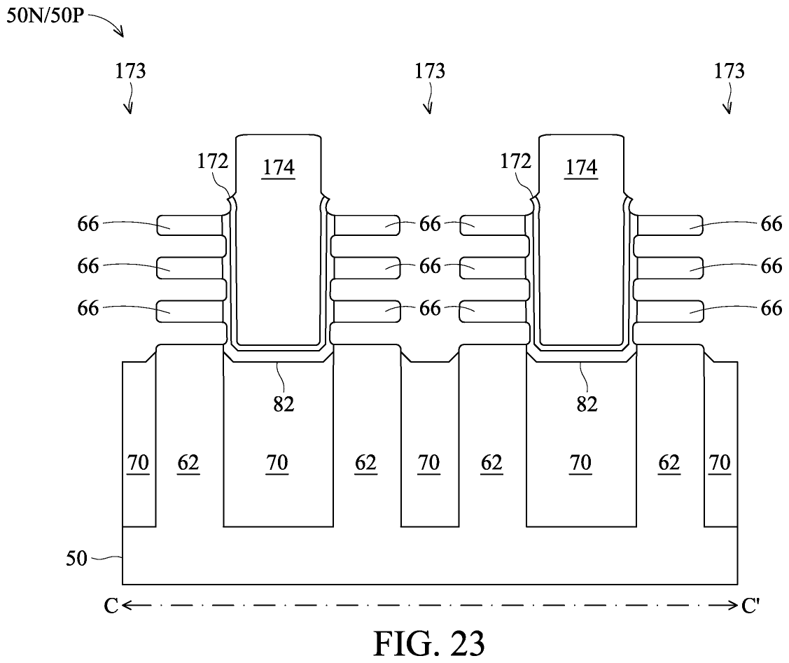

In FIG. 23, the remaining portions of the first nanostructures 64 are then removed to form openings in regions between the second nanostructures 66. The remaining portions of the first nanostructures 64 can be removed using any acceptable etch process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66 and expand the openings between the second nanostructures 66. The exposed portions of the second nanostructures 66 may be rounded after the trim and/or removal processes.

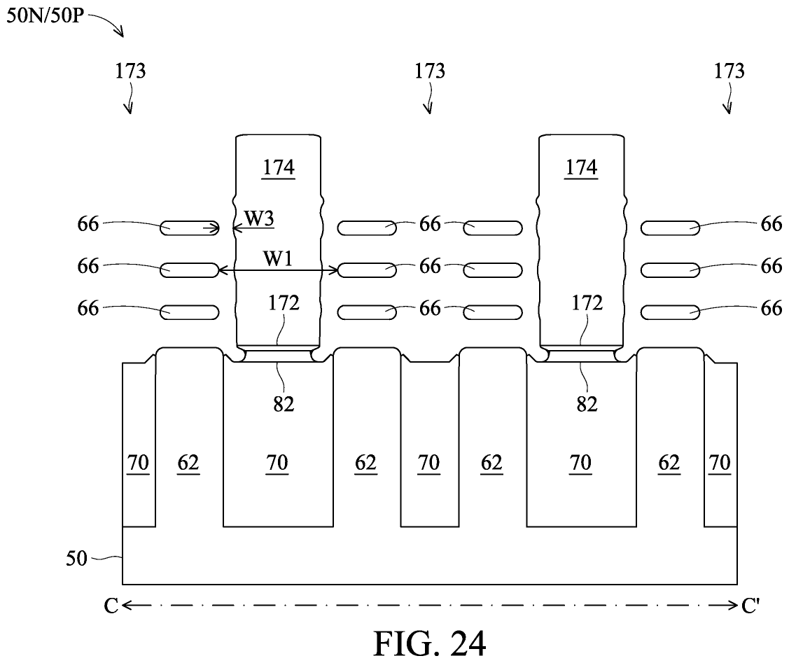

In FIG. 24, one or more etching steps are performed to remove the portions of the dummy dielectrics 82 and the liner layer 172 that are along the sidewalls of the dielectric material 174, in accordance with some embodiments. The one or more etching steps may be similar to etching steps described previously for FIG. 22. At least some portions of the dummy dielectrics 82 and the liner layer 172 between the dielectric material 174 and the isolation regions 70 may also be removed. As a result, in some cases, the dummy dielectrics 82 and/or the liner layer 120 may be recessed from sidewalls of the dielectric material 174 in the cross-sectional view. The exposed portions of the second nanostructures 66 may be rounded after the removal process. Additionally, removing the portions of the liner layer 172 forms openings between the dielectric material 174 and the nanostructures 66. In some embodiments, a width W3 between nanostructures 66 and the dielectric material 174 may be in the range of about 4 nm to about 10 nm, though other distances are possible.

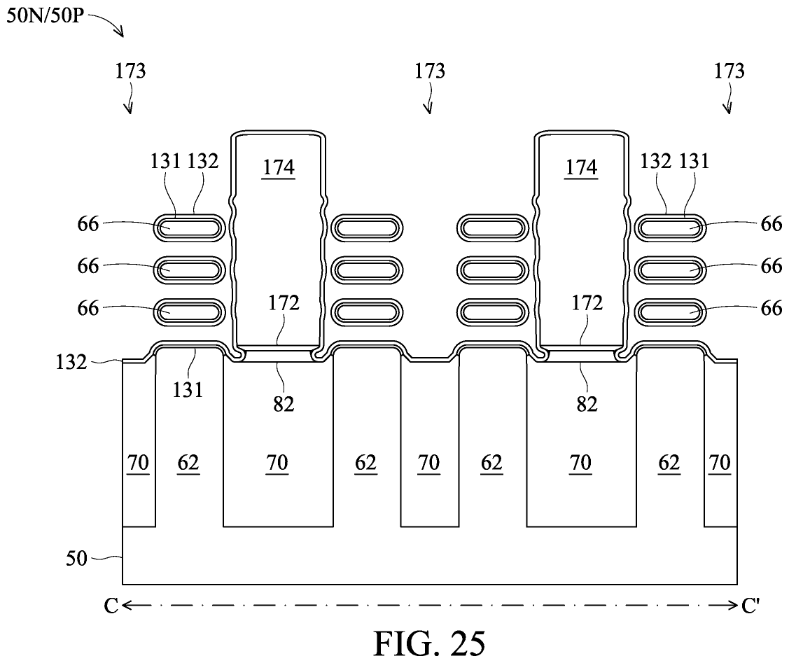

In FIG. 25, an interfacial layer 131 and a gate dielectric layer 132 are conformally formed on the channel regions of the second nanostructures 66, in accordance with some embodiments. Specifically, the interfacial layer 131 and the gate dielectric layer 132 are formed on the top surfaces of the fins 62; on the top surfaces, the sidewalls, and the bottom surfaces of the second nanostructures 66; and on the top surfaces and sidewalls of the dielectric material 174. The interfacial layer 131 and the gate dielectric layer 132 wrap around all (e.g., four) sides of the second nanostructures 66. The formation methods of the interfacial layer 131 and the gate dielectric layer 132 may include molecular-beam deposition (MBD), ALD, PECVD, the like, or another suitable technique. In some embodiments, the interfacial layer 131 may comprise a material such as silicon oxide or the like. The gate dielectric layer 132 may include an oxide such as silicon oxide or a metal oxide, a silicate such as a metal silicate, combinations thereof, multi-layers thereof, or the like. The gate dielectric layer 132 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The interfacial layer 131 and the gate dielectric layer 132 may include any acceptable number of layers.

In some embodiments, the work function of the gate dielectric layer 132 may be tuned by conformally depositing a work function tuning layer (not separately illustrated) on the gate dielectric layer 132, performing an annealing process, and then removing the work function tuning layer. The work function tuning layer may comprise a metal, a metal oxide, the like, or a combination thereof, which may be deposited using any suitable process. The annealing process drives the work function tuning layer into the gate dielectric layer 132 to change the work function. The annealing process may comprise a temperature in the range of about 300° C. to about 1000° C., though other temperatures are possible. After performing the annealing process, the work function tuning layer may be removed using a suitable etching process. The use of a work function tuning layer as described above is optional.

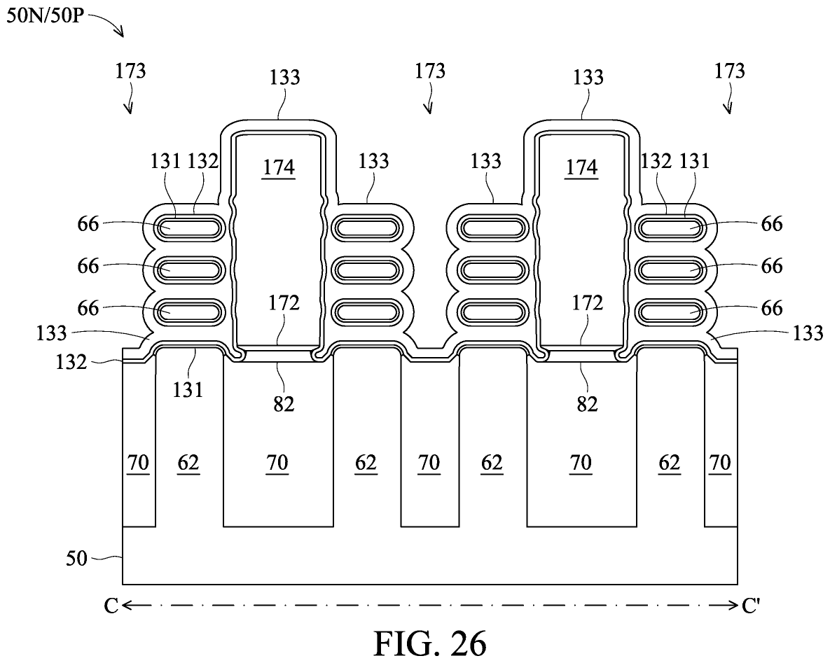

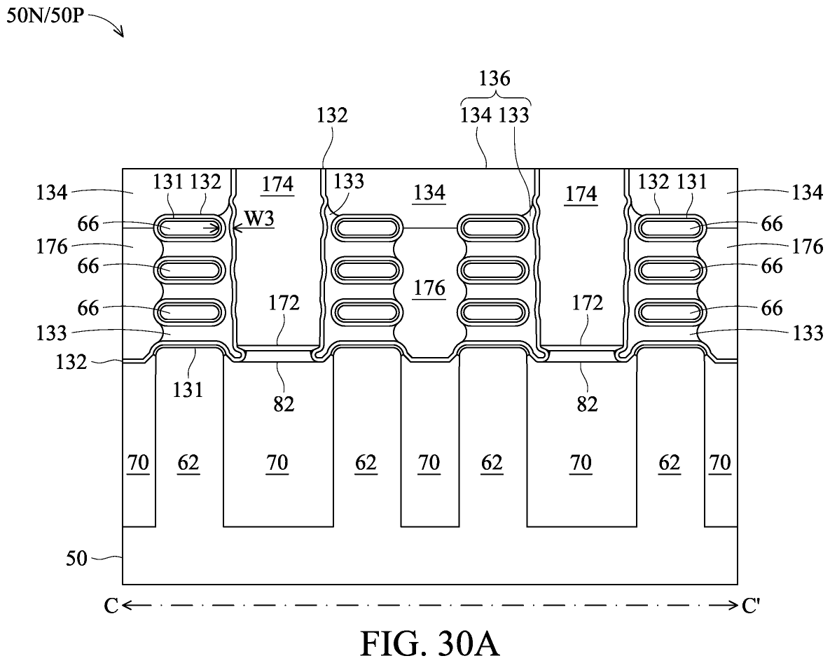

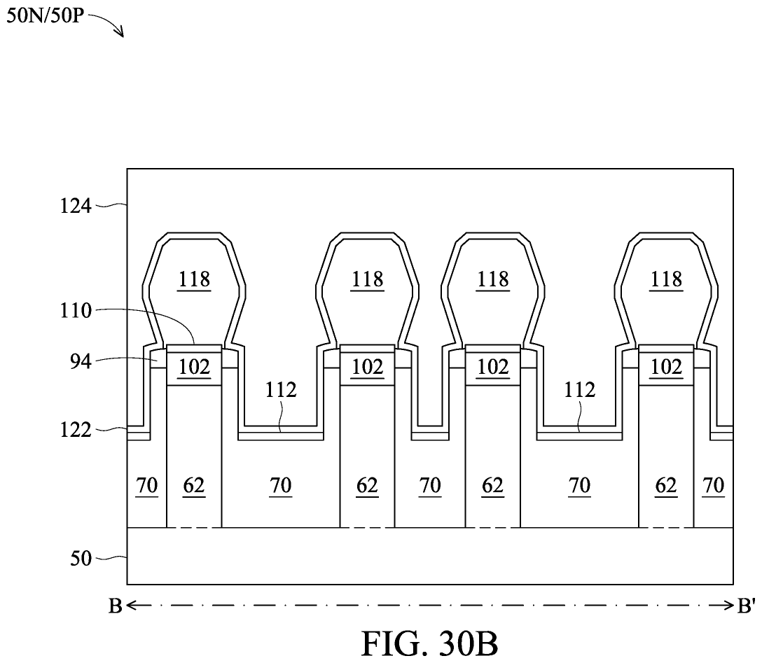

In FIG. 26, a gate electrode layer 133 is conformally formed over the channel regions of the second nanostructures 66, in accordance with some embodiments. The gate electrode layer 133, along with the subsequently formed gate electrode layer 134 (see FIG. 30A) forms gate electrodes for the nanostructure-FETs. The gate electrode layer 133 fills the remaining portions of the regions between the second nanostructures 66 such that respective portions of the gate electrode layer 133 wrap around respective second nanostructures 66, thereby completely filling regions between the respective second nanostructures 66. The gate electrode layer 133 is deposited on the gate dielectric layer 132 until it is thick enough to merge and seam together between adjacent nanostructures 66. The gate electrode layer 133 is also deposited over the sidewalls of the dielectric material 174 and fills the regions between the nanostructures 66 and the dielectric material 174. The gate electrode layer 133 may be formed of a metal-containing material such as titanium nitride, titanium oxide, tantalum nitride, tantalum carbide, tungsten, cobalt, ruthenium, aluminum, the like, or a combination thereof. The gate electrode layer 133 may be deposited using a suitable technique, such as CVD, ALD, plating, or the like.

In some embodiments, a sidewall of the gate electrode layer 133 is defined by the location and profile of the sidewall of the adjacent dielectric material 174. This sidewall of the gate electrode layer 133 also defines a sidewall (e.g. an “end-cap”) of the gate electrodes of the nanostructure-FETs. Accordingly, a thickness of the gate electrode layer 133 between the nanostructures 66 and the dielectric material 174 can be controlled by controlling the width, location, and profile of the dielectric material 174. In this manner, the size of the gate electrodes can be controlled by controlling the width, location, and profile of the dielectric material 174. In some cases, the formation of dielectric walls as described herein can allow for more uniform sidewalls, more vertical sidewall profiles, and more uniform sizes of the gate electrodes of nanostructure-FETs. Forming the dielectric material 174 as described herein can also allow for a smaller “end-cap” distance between the nanostructures 66 and the gate electrodes, which can improve device density and reduce parasitic capacitances.

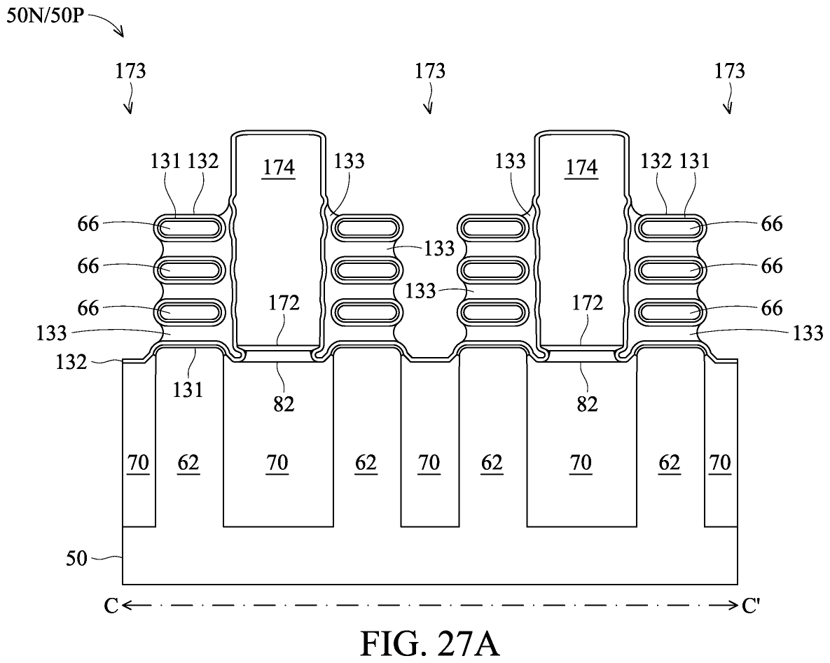

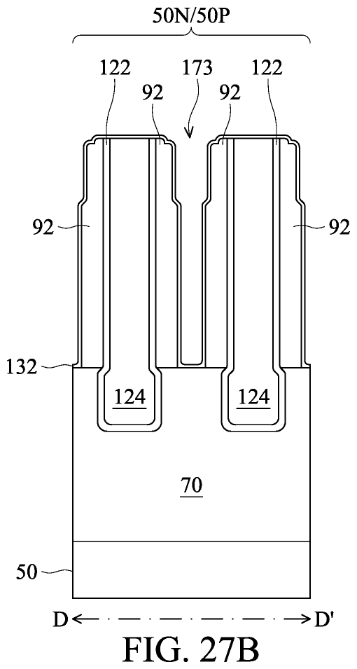

In FIGS. 27A-27B, an etch-back process is performed to remove portions of the gate electrode layer 133, in accordance with some embodiments. The etch-back process may comprise a suitable wet etch or dry etch, which may be isotropic or anisotropic. As shown in FIGS. 27A-27B, the etch-back process removes portions of the gate electrode layer 133 and exposes underlying portions of the gate dielectric layer 132. In some embodiments, the etch-back process removes portions of the gate electrode layer 133 from over surfaces of the isolation region 70, the dielectric material 174, and the gate spacers 92. The etch-back process also removes portions of the gate electrode layer 133 from over sidewall surfaces of the nanostructures 66 and from over top surfaces of the topmost nanostructures 66. In this manner, the gate dielectric layer 132 on sidewalls of the nanostructures 66 that are adjacent the dielectric material 174 remains covered by the gate electrode layer 133, and the gate dielectric layer 132 on sidewalls of the nanostructures 66 that are farther from the dielectric material 174 is exposed.

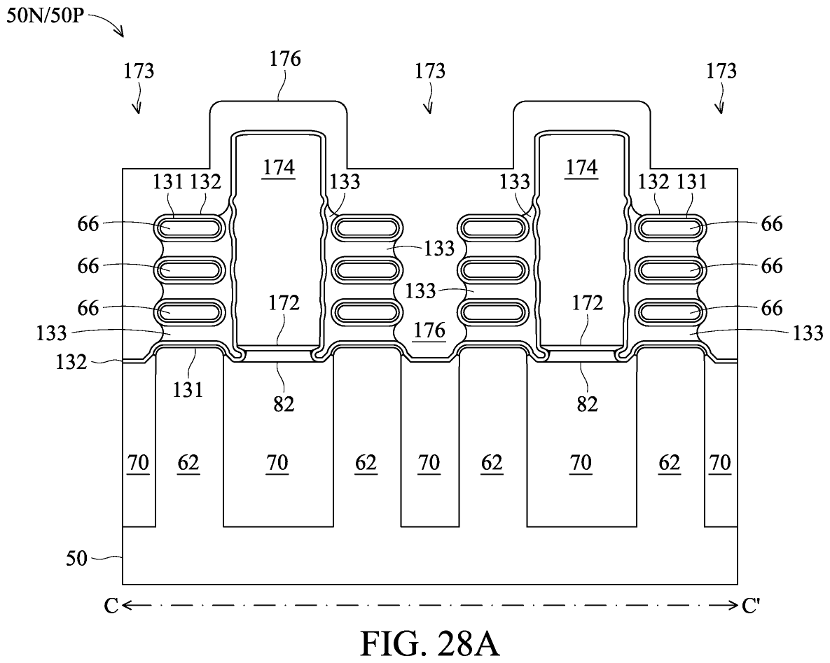

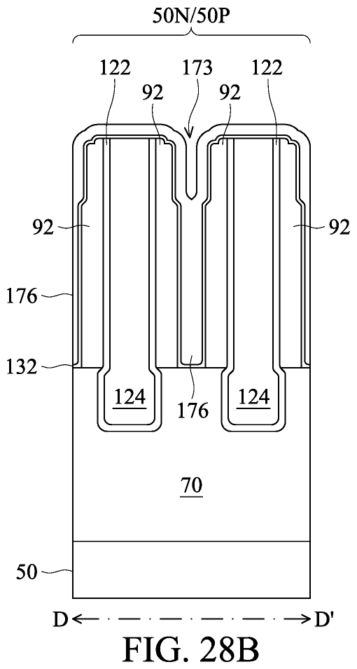

In FIGS. 28A-28B, an isolation material 176 is deposited over the structure and within the recesses 173, in accordance with some embodiments. The isolation material 176 forms isolation structures that isolate and separate portions of the gate electrodes, described in greater detail below. Accordingly, the isolation material 176 may also be referred to as “isolation structures” herein, in some cases. As shown in FIG. 28A, the isolation material 176 may fill regions of the recesses 173 between nanostructures 66. As shown in FIG. 28B, the isolation material 176 may partially fill regions of the recesses 173 between gate spacers 92. In some embodiments, due to the larger width of the recesses 173 between thinned portions of the gate spacers 92, the isolation material 176 may not completely fill regions of the recesses 173 between thinned portions of the gate spacers 92. In other words, the isolation material 176 deposited on upper sidewalls of the gate spacers 92 may remain unmerged, as shown in FIG. 28B. In this manner, trimming the gate spacers 92 can facilitate filling of the recesses 173 with the isolation material 176. The isolation material 176 may comprise acceptable dielectric materials such as aluminum oxide, aluminum nitride, silicon oxide, silicon nitride, silicon carbonitride, silicon oxycarbonitride, or the like, which may be formed by a deposition process such as CVD, ALD, or the like. In other embodiments, the isolation material 176 comprises silicon. Other materials or deposition techniques are possible.

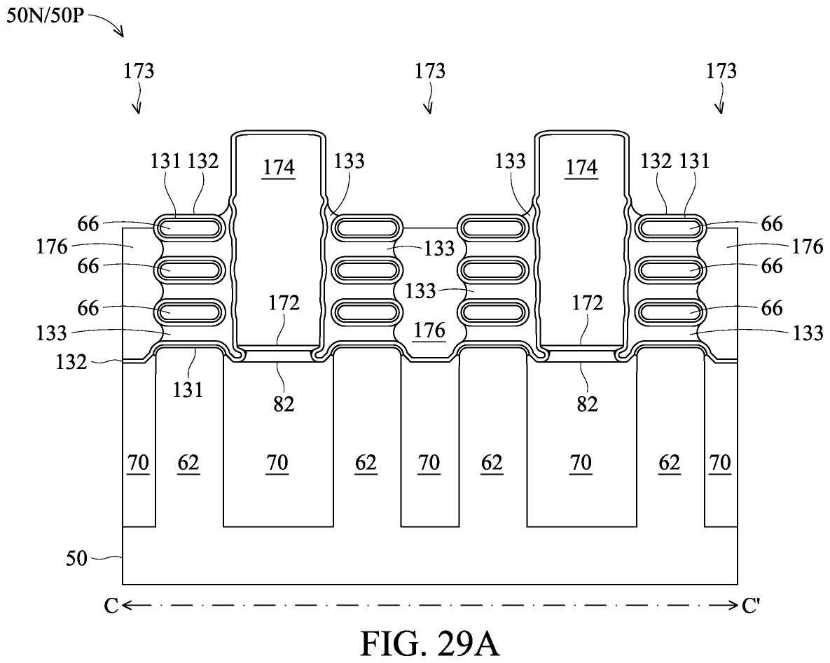

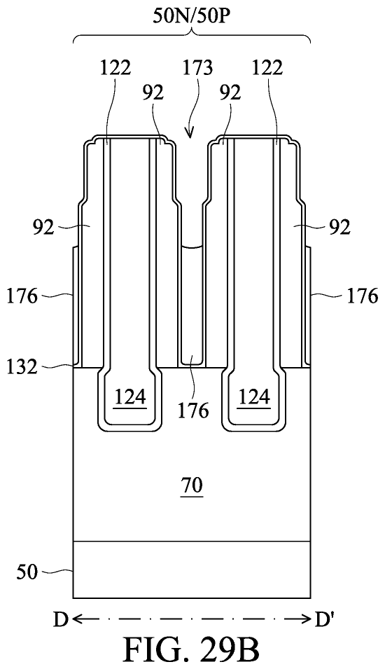

In FIGS. 29A-29B, an etch-back process is performed to remove portions of the isolation material 176, in accordance with some embodiments. The etch-back process may comprise a suitable wet etch or dry etch, which may be isotropic or anisotropic. As shown in FIGS. 29A-29B, the etch-back process removes portions of the isolation material 176 over surfaces of the dielectric material 174 and removes portions of the isolation material 176 over surfaces of the top-most nanostructures 66. In some embodiments, after the etch-back process, top surfaces of the isolation material 176 are in the range of about 0 nm and about 6 nm below top surfaces of the top-most nanostructures 66. In some cases, the trimming of the gate spacers 92 facilitates the etching of the isolation material 176 in the etch-back process. After the etch-back process, the remaining portions of the isolation material 176 form isolation structures between adjacent nanostructures 66. In some embodiments, pairs of nanostructures 66 are alternatingly separated by the dielectric material 174 (e.g., a dielectric wall) and the isolation material 176 (e.g., an isolation structure), as shown in FIG. 29A.

In FIGS. 30A-30B, a gate electrode material 134 is deposited to form gate electrodes 136, in accordance with some embodiments. The gate electrode material 134 is deposited on surfaces of the gate electrode layer 133 and the isolation material 176 and over the top-most nanostructures 66. The gate electrode layer 133 and the gate electrode material 134 together form gate electrodes 136 for the nanostructure-FETs. In some cases, the gate electrodes 136, the gate dielectric layers 132, and the interfacial layer 131 may collectively referred to as “gate structures” herein. The gate electrode material 134 comprise material(s) similar to the gate electrode layer 133, or may comprise other materials. For example, in some embodiments, the gate electrode material 134 comprises a metal-containing material such as tungsten, cobalt, ruthenium, aluminum, combinations thereof, multi-layers thereof, or the like. The gate electrode material 134 may be deposited using a suitable technique, such as CVD, ALD, plating, or the like. After depositing the gate electrode material 134, a planarization process (e.g., a CMP process or a grinding process) may be performed to remove excess gate electrode material 134. The planarization process may also remove portions of the dielectric material 174, forming dielectric walls. After performing the planarization process, top surfaces of the gate electrode material 134, the dielectric material 174, and/or the gate dielectrics 132 may be approximately level or coplanar.

As shown in FIG. 30A, forming the gate electrode layer 133 as described herein allows the gate electrodes 136 to extend along sidewalls of nanostructures 66 and extend between adjacent nanostructures 66. In this manner, the gate electrodes 136 described herein may have a “x-shaped” (e.g., a “pi-shaped”) profile between the dielectric walls and the isolation structures. Forming the gate electrode layer 133 as described herein also allows the isolation structures to extend along sidewalls of nanostructures 66. In this manner, an isolation structure may be surrounded on its sides and top by a gate electrode 136. By forming an isolation structure within a gate electrode 136 as described herein, parasitic capacitances between the gate electrodes 136 and the epitaxial source/drain regions 118 may be reduced, which can improve device performance. For example, referring to FIGS. 30A-30B, capacitances between the middle two epitaxial source/drain regions 118 of FIG. 30B and the middle gate electrode 136 of FIG. 30A may be reduced.

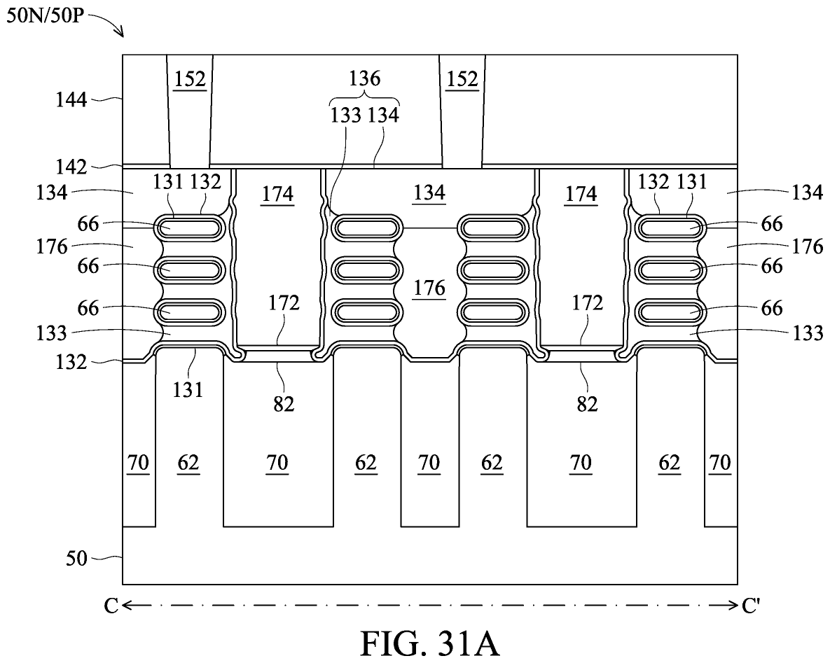

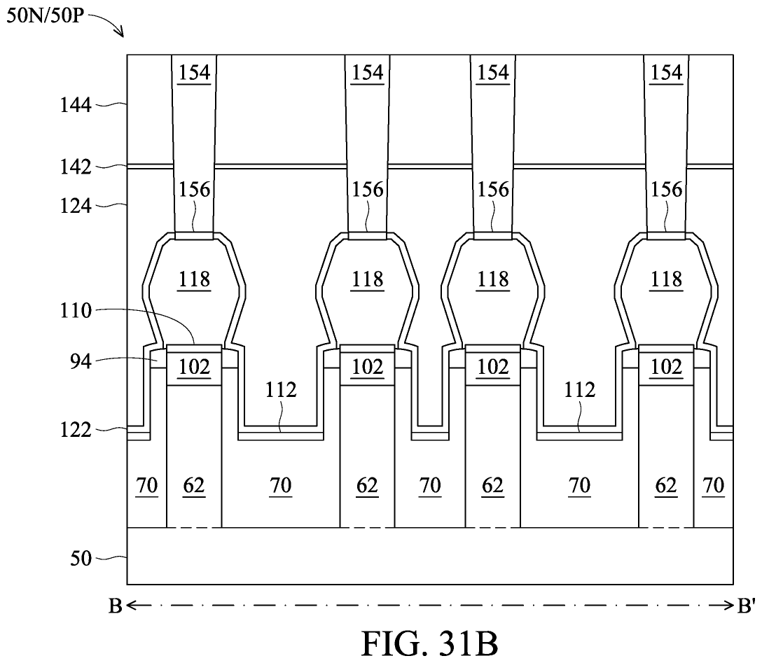

In FIGS. 31A-31B, a second ILD 144 is deposited over the gate electrodes 136 and the dielectric material 174. In some embodiments, the second ILD 144 is a flowable film formed by a flowable CVD method. In some embodiments, the second ILD 144 is formed of a dielectric material such as PSG, BSG, BPSG, USG, or the like, which may be formed by any suitable deposition process, such as CVD, PECVD, or the like. In some embodiments, an optional etch stop layer (ESL) 142 is deposited before depositing the second ILD 144. The ESL 142 may be formed of a dielectric material having a high etching selectivity from the etching of the second ILD 144, such as silicon nitride, silicon oxide, silicon oxynitride, or the like, which may be formed by any suitable deposition process, such as CVD, ALD, or the like.

Further in FIGS. 31A-31B, gate contacts 152 and source/drain contacts 154 are formed to contact, respectively, the gate electrodes 164 and the epitaxial source/drain regions 118. The gate contacts 152 may be physically and electrically coupled to the gate electrodes 164. The source/drain contacts 154 may be physically and electrically coupled to the epitaxial source/drain regions 118.

As an example to form the gate contacts 152 and the source/drain contacts 154, openings for the gate contacts 152 are formed through the second ILD 144 and the ESL 142, and openings for the source/drain contacts 154 are formed through the second ILD 144, the ESL 142, the first ILD 124, and the CESL 122. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 144. The remaining liner and conductive material form the gate contacts 152 and the source/drain contacts 154 in the openings. The gate contacts 152 and the source/drain contacts 154 may be formed in distinct processes, or may be formed in the same process. Although shown as being formed in the same cross-sections, it should be appreciated that each of the gate contacts 152 and the source/drain contacts 154 may be formed in different cross-sections, which may avoid shorting of the contacts.

Optionally, metal-semiconductor alloy regions 156 are formed at the interfaces between the epitaxial source/drain regions 118 and the source/drain contacts 154. The metal-semiconductor alloy regions 156 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 156 can be formed before the material(s) of the source/drain contacts 154 by depositing a metal in the openings for the source/drain contacts 154 and then performing a thermal annealing process. The metal can be any metal capable of reacting with the semiconductor materials (e.g., silicon, silicon carbide, silicon germanium, germanium, etc.) of the epitaxial source/drain regions 118 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 154, such as from surfaces of the metal-semiconductor alloy regions 156. The material(s) of the source/drain contacts 154 can then be formed on the metal-semiconductor alloy regions 156.

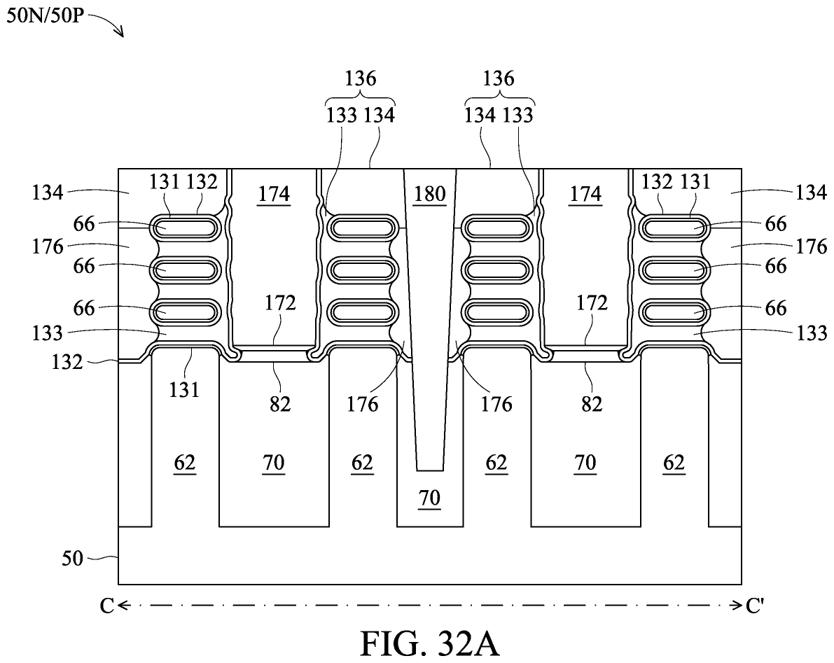

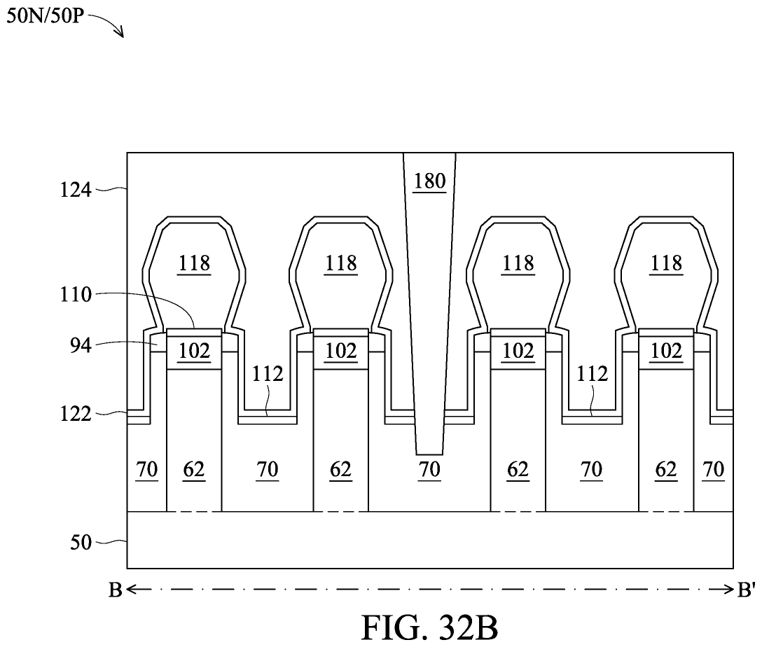

FIGS. 32A-32B illustrate the formation of an optional gate isolation region 180, in accordance with some embodiments. The structure shown in FIGS. 32A and 32B is similar to the structure shown in FIGS. 30A and 30B, respectively, except for the presence of the gate isolation region 180. The gate isolation region 180 is an insulating structure that extends through the gate electrode material 134 and into the isolation material 176 to separate a single gate electrode into two adjacent electrically isolated gate electrodes 136. In this manner, a gate isolation region 180 may “cut” gate electrodes. FIGS. 32A-32B show the gate isolation region 180 extending fully through the isolation material 176 and fully through the ILD 124 and into the isolation region 70. In other embodiments, the gate isolation region 180 may extend only partially into the isolation material 176, only partially into the ILD 124, or fully through the isolation region 70 and into the substrate 50. In still other embodiments, the gate isolation region 180 may contact a top surface of the isolation material 176 without penetrating into it. As shown in FIG. 32A, a width of the gate isolation region 180 may be less than a width of the isolation material 176. Due to the presence of the isolation material 176, variation of the threshold voltage of the nanostructure-FETs due to variation of the size or position of the gate isolation region 180 can be reduced. In this manner, the uniformity of nanostructure-FETs can be improved.

In some embodiments, the gate isolation regions 180 may be formed by forming recesses (not separately illustrated) and then filling the recesses with one or more dielectric materials. The recesses may be formed using suitable photolithography and etching techniques. For example, a patterned mask may be formed over the structure, and then one or more etching steps may be performed using the patterned mask as an etch mask. Bottom surfaces of the recesses may be at the top surfaces of the isolation material 176, below top surfaces of the isolation material 176, or below bottom surfaces of the isolation material 176. The gate isolation regions 180 may comprise acceptable dielectric materials such as aluminum oxide, aluminum nitride, silicon oxide, silicon nitride, silicon carbonitride, silicon oxycarbonitride, or the like, which may be formed by a deposition process such as CVD, ALD, or the like. Other materials or deposition techniques are possible. After filling the recesses with the dielectric material(s), a planarization process may be performed to remove excess dielectric material(s), forming the gate isolation regions 180. In some embodiments, after performing the planarization process, top surfaces of the gate isolation regions 180, dielectric material 174, ILD 124, and gate electrodes 136 may be approximately level or coplanar.

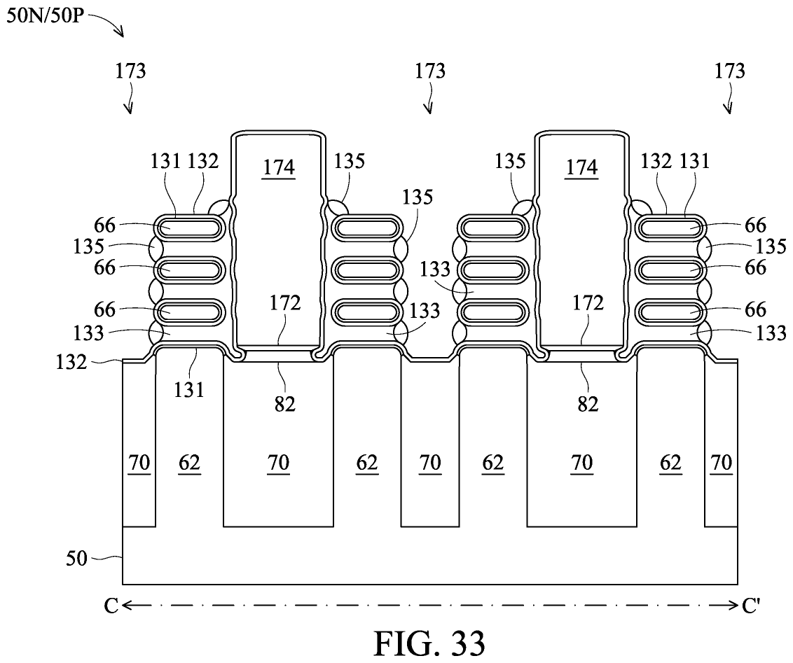

FIG. 33 shows an embodiment in which additional metal 135 is selectively grown on the gate electrode layer 133. The additional metal 135 may be grown after performing the etch-back process described previously for FIG. 27A. Accordingly, the structure shown in FIG. 33 is similar to the structure shown in FIG. 27A, except that additional metal 135 has been grown on exposed portions of the gate electrode layer 133. In this manner, the gate electrodes 136 may comprise the gate electrode layer 133, the gate electrode material 134, and the additional metal 135.

The additional metal 135 may be a material similar to that of the gate electrode layer 133 and/or the gate electrode material 134. The additional metal 135 may be deposited using a selective process such as ALD, plating, or another suitable technique. The additional metal 135 protrudes from the gate electrode layer 133 and extends over surfaces of the nanostructures 66. Increasing the surface area of the nanostructures 66 covered by the gate electrodes 136 in this manner can allow for enhanced gate control by the gate electrodes 136 and improved device performance. In some embodiments, the additional metal 135 is deposited to a thickness in the range of about 0 nm to about 3 nm, though other thicknesses are possible. As shown in FIG. 33, in some embodiments, the sidewalls of the nanostructures 66 remain uncovered by the additional metal 135. In other embodiments, the additional metal 135 covers the sidewalls of the nanostructures 66. The additional metal 135 covers the gate electrode layer 133, and thus in subsequent steps, the isolation material 176 is deposited on the additional metal 135 instead of on the gate electrode layer 133.

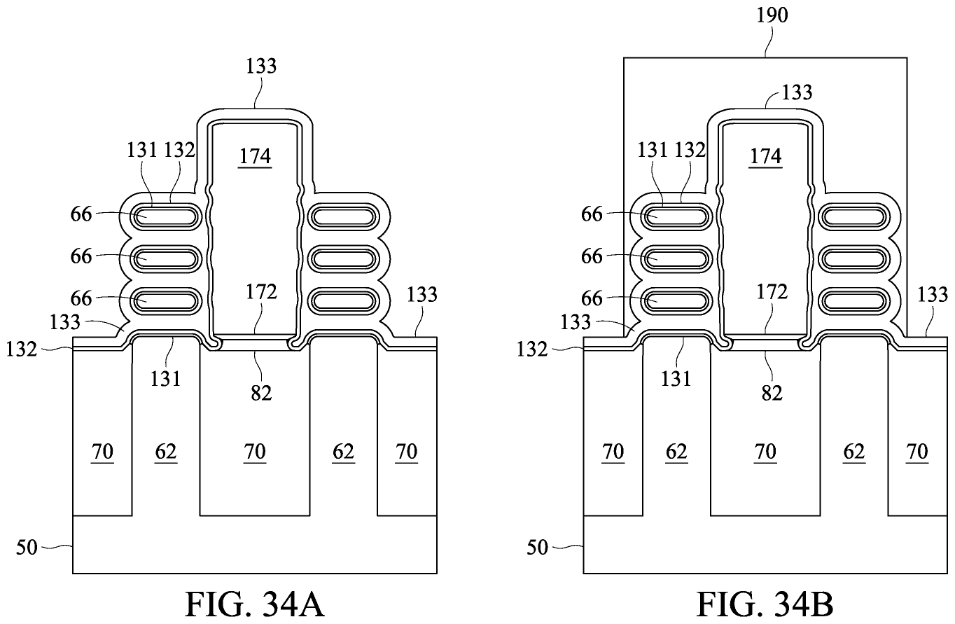

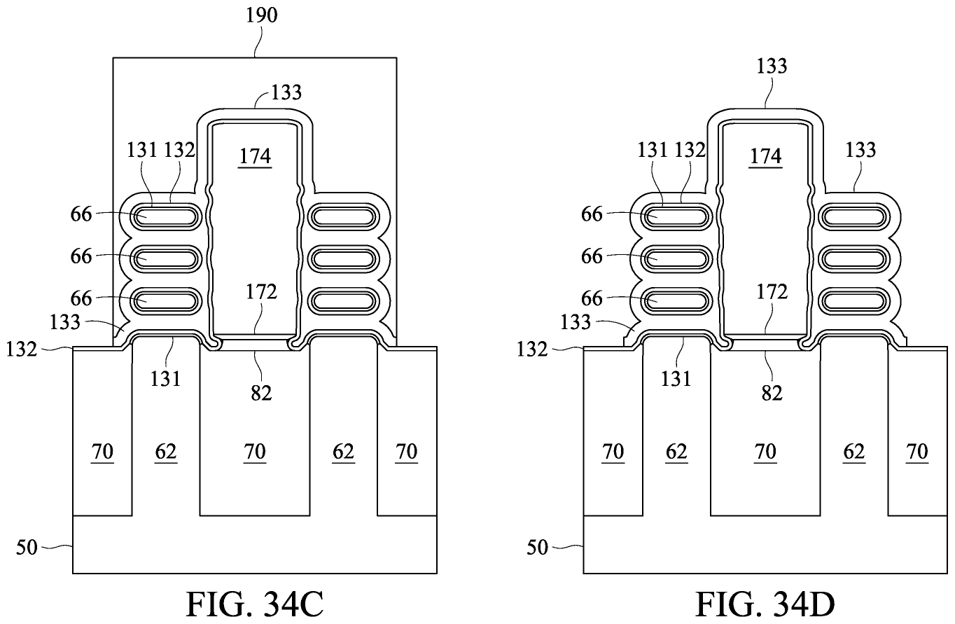

In some embodiments, the etch-back process described previously for FIGS. 27A-27B does not remove the gate electrode layer 133 from surfaces of the nanostructures 66. As an example, FIGS. 34A through 34D illustrate an embodiment process in which the gate electrode layer 133 around the nanostructures 66 is protected during the etch-back process, in accordance with some embodiments. FIG. 34A illustrates a structure after the gate electrode layer 133 has been deposited, similar to the structure shown previously in FIG. 26. In FIG. 34B, a photoresist 190 or other masking material has been formed over the structure and patterned. The photoresist 190 is patterned to expose regions of the gate electrode layer 133 adjacent the nanostructures 66 while leaving the photoresist 190 covering the gate electrode layer 133 over the nanostructures 66. The photoresist 190 can be formed by using a spin-on technique and can be patterned using acceptable photolithography techniques. In FIG. 34C, the etch-back process or another etching process is performed to remove the exposed portions of the gate electrode layer 133. As shown in FIG. 34C, the photoresist 190 protects the gate electrode layer 133 on the nanostructures 66 from the etch-back process. In FIG. 34D, the photoresist 190 is removed using a suitable process, such as an ashing process. After removing the photoresist 190, the process may continue as described in FIGS. 28A-31B. Increasing the surface area of the nanostructures 66 covered by the gate electrodes 136 in this manner can allow for enhanced gate control by the gate electrodes 136 and improved device performance. The gate electrode layer 133, and thus in subsequent steps, the isolation material 176 is separated from the nanostructures 66 by the gate electrode layer 133.

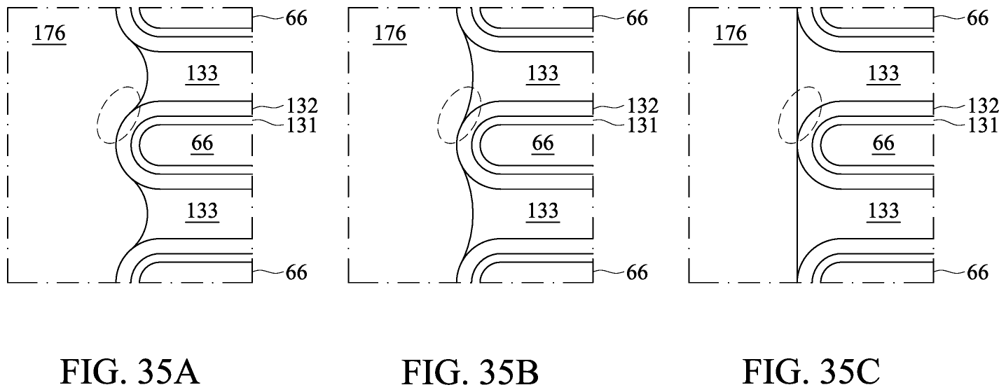

The gate electrode layer 133 shown in FIGS. 31A-31B has a concave profile between nanostructures 66 due to the etch-back process of FIGS. 27A-28B, but in other embodiments the gate electrode layer 133 may have a different profile than shown. As examples, FIGS. 35A, 35B, and 35C illustrate magnified views of gate electrode layer 133 at the isolation material 176, in accordance with some embodiments. FIG. 35A illustrates an example of the gate electrode layer 133 having a concave profile between adjacent nanostructures 66, similar to the embodiment shown in FIGS. 31A-31B. A concave profile of the gate electrode layer 133 corresponds to a convex profile of the adjacent isolation material 176. As indicated by the dotted ellipse in FIG. 35A, in some cases the etch-back process removes the gate electrode layer 133 from over sidewalls of the nanostructures 66. Removing the gate electrode layer 133 from the sidewalls may expose regions of the gate dielectrics 132, which are then subsequently covered by the isolation material 176.

In some cases, a deeper concave profile between nanostructures 66 can correspond to less gate electrode material 133 over sidewalls of the nanostructures. This is shown in FIG. 35B, in which the gate electrode layer 133 has a less concave profile between nanostructures 66 than in FIG. 35A. The isolation material 176 has a correspondingly less convex profile. Accordingly, more of the sidewall regions of the nanostructures 66 are covered by the gate electrode layer 133, as indicated by the dotted ellipse in FIG. 35B. In some embodiments, performing the etch-back process for a smaller duration of time may result in a less concave profile for the gate electrode layer 133 and also may result in the gate electrode layer 133 covering more of the sidewalls of the nanostructures 66. In some cases, covering more of the nanostructures 66 with the gate electrode layer 133 can result in greater gate control by the gate electrodes 136. For example, the embodiment of FIG. 35B may have greater gate control than the embodiment of FIG. 35A.

In FIG. 35C, the gate electrode layer 133 has an approximately flat (e.g., vertical) profile, with little or no concavity. The isolation material 176 has a correspondingly flat profile. Accordingly, more of the sidewall regions of the nanostructures 66 are covered by the gate electrode layer 133, as indicated by the dotted ellipse in FIG. 35C. In some cases, covering more of the nanostructures 66 with the gate electrode layer 133 can result in greater gate control by the gate electrodes 136. For example, the embodiment of FIG. 35C may have greater gate control than the embodiment of FIG. 35B. The gate electrode layer 133 profiles shown in FIGS. 35A-35C are illustrative examples, and other profiles are possible.

Embodiments may achieve advantages. Forming the dielectric walls 174 between adjacent groups of nanostructures 66 allows the adjacent groups of nanostructures 66 to be formed closer together. Device density may thus be improved. In some cases, the use of dielectric walls 174 as described herein allows for more uniformly vertical sidewalls of the gate electrodes 136, which can improve device uniformity, such as reduced threshold voltage variation. Additionally, the use of dielectric walls 174 as described herein can allow for smaller “end-cap” length of the gate electrodes 136, which can improve device density and reduce parasitic capacitances. Additionally, the formation of isolation structures 176 as described herein can reduce parasitic capacitances between the gate electrodes 136 and the epitaxial source/drain regions 118, which can improve device performance. The use of isolation structures 176 can also allow for the formation of gate isolation regions 180 with reduced effect on the characteristics of the nanostructure-FETs, such as a reduced effect on the threshold voltage due to process variations.

In an embodiment, a device includes first nanostructures over a substrate; second nanostructures over the substrate, wherein the first nanostructures are laterally separated from the second nanostructures by an isolation structure between the first nanostructures and the second nanostructures; a first gate structure around each first nanostructure and around each second nanostructure, wherein the first gate structure extends over the isolation structure; third nanostructures over the substrate; and a second gate structure around each third nanostructure, wherein the second gate structure is separated from the first gate structure by a dielectric wall. In an embodiment, top surfaces of the first gate structure, the second gate structure, and the dielectric wall are level. In an embodiment, a top surface of the isolation structure is closer to the substrate than a top surface of the first nanostructures. In an embodiment, the device includes a gate isolation structure extending from a top surface of the first gate structure to a top surface of the isolation structure. In an embodiment, the isolation structure protrudes laterally between adjacent first nanostructures. In an embodiment, the third nanostructures are separated from the dielectric wall by the second gate structure. In an embodiment, a lateral distance between a third nanostructure and the dielectric wall is in the range of 4 nm to 10 nm. In an embodiment, the device includes a gate dielectric layer around the first nanostructures, along a sidewall of the dielectric wall, and along a bottom surface of the isolation structure.

In an embodiment, a device includes a dielectric wall over an isolation region; an isolation structure over the isolation region, wherein a height of the dielectric wall is greater than a height of the isolation structure; a stack of first nanostructures between the dielectric wall and the isolation structure; a gate dielectric layer includes first portions respectively surrounding each first nanostructure and a second portion extending on a sidewall of the dielectric wall; and a gate electrode layer extending between adjacent first nanostructures and extending on the second portion of the gate dielectric layer, wherein the isolation structure physically contacts the gate electrode layer and the first portions of the gate dielectric layer. In an embodiment, a top surface of the isolation structure is in the range of 0 nm to 6 nm below a top surface of the stack of first nanostructures. In an embodiment, the second portion of the gate dielectric layer extends between the dielectric wall and the gate electrode layer. In an embodiment, at least one sidewall surface of the isolation structure is free of the gate dielectric layer. In an embodiment, the gate electrode layer physically contacts a top surface of the isolation structure. In an embodiment, the device includes a stack of second nanostructures, wherein the isolation structure is between the stack of first nanostructures and the stack of second nanostructures. In an embodiment, the gate electrode layer extends between adjacent second nanostructures. In an embodiment, the device includes a gate isolation structure extending through the gate electrode layer and through the isolation structure and extending into the isolation region.

In an embodiment, a method includes forming first nanostructures over a substrate, second nanostructures adjacent the first nanostructures, and third nanostructures adjacent the second nanostructures; depositing a first dielectric material between the first nanostructures and the second nanostructures to form a first dielectric structure; forming a first gate structure around the first nanostructures and on a first sidewall of the first dielectric structure; forming a second gate structure around the second nanostructures and on a second sidewall of the first dielectric structure; forming a third gate structure around the third nanostructures; depositing a second dielectric material between the second nanostructures and the third nanostructures to form a second dielectric structure; and depositing a conductive material over the second gate structure, the third gate structure, and the second dielectric structure, wherein the conductive material electrically connects the second gate structure and the third gate structure. In an embodiment, the first gate structure is isolated from the second gate structure by the first dielectric structure. In an embodiment, top surfaces of the first dielectric structure and the conductive material are level. In an embodiment, the method includes performing an etch-back process on the first gate structure, the second gate structure, and the third gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
first nanostructures over a substrate;
second nanostructures over the substrate, wherein the first nanostructures are laterally separated from the second nanostructures by an isolation structure between the first nanostructures and the second nanostructures;
a first gate structure around each first nanostructure and around each second nanostructure, wherein the first gate structure extends over the isolation structure;
third nanostructures over the substrate; and
a second gate structure around each third nanostructure, wherein the second gate structure is separated from the first gate structure by a dielectric wall.

2. The device of claim 1, wherein top surfaces of the first gate structure, the second gate structure, and the dielectric wall are level.

3. The device of claim 1, wherein a top surface of the isolation structure is closer to the substrate than a top surface of the first nanostructures.

4. The device of claim 1 further comprising a gate isolation structure extending from a top surface of the first gate structure to a top surface of the isolation structure.

5. The device of claim 1, wherein the isolation structure protrudes laterally between adjacent first nanostructures.

6. The device of claim 1, wherein the third nanostructures are separated from the dielectric wall by the second gate structure.

7. The device of claim 6, wherein a lateral distance between a third nanostructure and the dielectric wall is in the range of 4 nm to 10 nm.

8. The device of claim 1 further comprising a gate dielectric layer around the first nanostructures, along a sidewall of the dielectric wall, and along a bottom surface of the isolation structure.

9. A device comprising:
a dielectric wall over an isolation region;
an isolation structure over the isolation region, wherein a height of the dielectric wall is greater than a height of the isolation structure;
a stack of first nanostructures between the dielectric wall and the isolation structure;
a gate dielectric layer comprising first portions respectively surrounding each first nanostructure and a second portion extending on a sidewall of the dielectric wall; and
a gate electrode layer extending between adjacent first nanostructures and extending on the second portion of the gate dielectric layer, wherein the isolation structure physically contacts the gate electrode layer and the first portions of the gate dielectric layer.

10. The device of claim 9, wherein a top surface of the isolation structure is in the range of 0 nm to 6 nm below a top surface of the stack of first nanostructures.

11. The device of claim 9, wherein the second portion of the gate dielectric layer extends between the dielectric wall and the gate electrode layer.

12. The device of claim 9, wherein at least one sidewall surface of the isolation structure is free of the gate dielectric layer.

13. The device of claim 9, wherein the gate electrode layer physically contacts a top surface of the isolation structure.

14. The device of claim 9 further comprising a stack of second nanostructures, wherein the isolation structure is between the stack of first nanostructures and the stack of second nanostructures.

15. The device of claim 14, wherein the gate electrode layer extends between adjacent second nanostructures.

16. The device of claim 9 further comprising a gate isolation structure extending through the gate electrode layer and through the isolation structure and extending into the isolation region.

17. A method comprising:
forming first nanostructures over a substrate, second nanostructures adjacent the first nanostructures, and third nanostructures adjacent the second nanostructures;
depositing a first dielectric material between the first nanostructures and the second nanostructures to form a first dielectric structure;
forming a first gate structure around the first nanostructures and on a first sidewall of the first dielectric structure;
forming a second gate structure around the second nanostructures and on a second sidewall of the first dielectric structure;
forming a third gate structure around the third nanostructures;
depositing a second dielectric material between the second nanostructures and the third nanostructures to form a second dielectric structure; and
depositing a conductive material over the second gate structure, the third gate structure, and the second dielectric structure, wherein the conductive material electrically connects the second gate structure and the third gate structure.

18. The method of claim 17, wherein the first gate structure is isolated from the second gate structure by the first dielectric structure.

19. The method of claim 17, wherein top surfaces of the first dielectric structure and the conductive material are level.

20. The method of claim 17 further comprising performing an etch back process on the first gate structure, the second gate structure, and the third gate structure.
